(19) United States
(12) Patent Application Publication
(10) Pub. No.: US 2024/0420616 A1
(43) Pub. Date: Dec. 19, 2024

(54) IMAGE PROCESSING SYSTEM

(71) Applicant: Semiconductor Energy Laboratory Co., Ltd., Atsugi-shi, Kanagawa-ken (JP)

(72) Inventors: Shunpei YAMAZAKI, Setagaya (JP); Koji KUSUNOKI, Isehara (JP); Daisuke KUBOTA, Atsugi (JP); Kensuke YOSHIZUMI, Atsugi (JP)

(21) Appl. No.: 18/706,408

(22) PCT Filed: Nov. 7, 2022
(86) PCT No.: PCT/IB2022/060665

§ 371 Date: May 1, 2024

(30) Foreign Application Priority Data
Nov. 18, 2021 (JP) 2021-187830

(51) Int. Cl. G09G 3/20; G06F 3/042; G06F 3/044; G06F 3/04886; G09G 3/3233; H10K 59/40

(52) U.S. Cl. CPC G09G 3/2092; G06F 3/04886; G09G 3/2007; G06F 3/042; G06F 3/044; G09G 3/3233; G09G 2300/0814; G09G 2300/0842; G09G 2310/04; G09G 2320/0686; G09G 2320/10; G09G 2330/021; G09G 2340/0435; G09G 2354/00; G09G 2370/022; H10K 59/40

(57) ABSTRACT

A display apparatus or an electronic device with low power consumption is provided. An image processing system capable of reducing the amount of communication data is provided. The image processing system includes a display portion, an input portion, an arithmetic portion, and an image processing portion. The input portion has a function of obtaining positional information on pointing operation by a user. The arithmetic portion has a function of defining a first region and a second region in accordance with the positional information. The image processing portion has a function of executing image processing on a portion of a first image to generate a second image, the portion corresponding to the first region. The display portion has a function of displaying the second image.

### TECHNICAL FIELD

One embodiment of the present invention relates to an electronic device. One embodiment of the present invention relates to a method for driving an electronic device. One embodiment of the present invention relates to a display apparatus. One embodiment of the present invention relates to a method for driving a display apparatus. One embodiment of the present invention relates to a program.

Note that one embodiment of the present invention is not limited to the above technical field. Examples of the technical field of one embodiment of the present invention disclosed in this specification and the like include a semiconductor device, a display apparatus, a light-emitting apparatus, a power storage device, a storage device, an electronic device, a lighting device, an input device, an input/output device, a driving method thereof, and a fabrication method thereof. A semiconductor device refers to any device that can function by utilizing semiconductor characteristics.

### BACKGROUND ART

In recent years, information terminal devices, e.g., mobile phones such as smartphones, tablet information terminals, and notebook PCs (personal computers), have been widely used. Such a terminal device includes a screen for displaying an image and an input means such as a touch panel, a mouse, or a controller.

For example, products whose touch panel utilizes a capacitive touch sensor are widely used. Patent Document 1 discloses a structure of a touch panel whose display portion includes both an organic EL element and an organic photodiode and is capable of performing fingerprint authentication.

### REFERENCE

### Patent Document

[Patent Document 1] PCT International Publication No. 2020/053692

### SUMMARY OF THE INVENTION

### Problems to be Solved by the Invention

An object of one embodiment of the present invention is to provide a display apparatus or an electronic device having low power consumption. Another object of one embodiment of the present invention is to provide an image processing system, a display apparatus, or an electronic device capable of reducing the amount of communication data. Another object of one embodiment of the present invention is to provide a system that uses an electronic device not requiring high arithmetic performance. Another object of one embodiment of the present invention is to provide an image processing system, a display apparatus, or an electronic device that reduces power consumption without causing a user to have a feeling of strangeness.

An object of one embodiment of the present invention is to provide an image processing system having a novel structure, a display apparatus having a novel structure, or an electronic device having a novel structure. Another object of one embodiment of the present invention is to provide a method for driving the display apparatus having a novel structure or a method for driving the electronic device having a novel structure. Another object of one embodiment of the present invention is to at least alleviate at least one of problems of the conventional technique.

Note that the description of these objects does not preclude the existence of other objects. Note that one embodiment of the present invention does not have to achieve all the objects. Note that objects other than these can be derived from the description of the specification, the drawings, the claims, and the like.

### Means for Solving the Problems

One embodiment of the present invention is an image processing system that includes a display portion, an input portion, an arithmetic portion, and an image processing portion. The input portion has a function of obtaining positional information on pointing operation by a user. The arithmetic portion has a function of defining a first region and a second region in accordance with the positional information. The image processing portion has a function of executing image processing on a portion of a first image to generate a second image, the portion corresponding to the first region. The display portion has a function of displaying the second image.

It is preferable that the above structure further includes a communication portion having a function of communicating with a server. In that case, the image processing portion is preferably provided in the server. Alternatively, the image processing portion and the arithmetic portion are preferably provided in the server.

In any of the above structures, the image processing preferably makes resolution of the first region lower than resolution of the second region.

In any of the above structures, the image processing preferably makes a frequency in the first region lower than a frequency in the second region.

In any of the above structures, the image processing preferably makes a gray level in the first region lower than a gray level in the second region.

In any of the above structures, the input portion preferably includes a touch sensor. In that case, the touch sensor further preferably includes a capacitive sensor or an organic photodiode. In any of the above structures, it is preferable that in the first region, a moving image be displayed, and in the second region, a moving image moving more slowly than the moving image in the first region or a still image be displayed.

In any of the above structures, it is preferable that the second region include coordinates pointed by the user, and the first region surround the second region.

In any of the above structures, definition of the display portion is preferably higher than or equal to 50 ppi and lower than or equal to 1500 ppi.

### Effect of the Invention

According to one embodiment of the present invention, a display apparatus or an electronic device having low power consumption can be provided. Alternatively, a display apparatus or an electronic device capable of reducing the amount of communication data can be provided. Alternatively, a system that uses an electronic device not requiring high arithmetic performance can be provided. Alternatively, a display apparatus or an electronic device that reduces power consumption without causing a user to have a feeling of strangeness can be provided.

According to one embodiment of the present invention, an image processing system having a novel structure, a display apparatus having a novel structure, or an electronic device having a novel structure can be provided. According to another embodiment of the present invention, a method for driving the display apparatus having a novel structure or a method for driving the electronic device having a novel structure can be provided. According to one embodiment of the present invention, at least one of problems of the conventional technique can be at least alleviated.

Note that the description of these effects does not preclude the existence of other effects. Note that one embodiment of the present invention does not need to have all the effects. Note that effects other than these can be derived from the description of the specification, the drawings, the claims, and the like.

### BRIEF DESCRIPTION OF THE DRAWINGS

FIG. 1A and FIG. 1B are diagrams illustrating a structure example of an electronic device, and

FIG. 1C is a diagram illustrating a structure example of a system.

FIG. 2 is a diagram illustrating a structure example of a system.

FIG. 3 is a flow chart of operation of a system.

FIG. 4A and FIG. 4B are diagrams illustrating an operation example.

FIG. 5A and FIG. 5B are diagrams illustrating an operation example.

FIG. 6A to FIG. 6D are diagrams illustrating operation examples.

FIG. 7A to FIG. 7D are diagrams illustrating operation examples.

FIG. 8A and FIG. 8B are diagrams illustrating operation examples.

FIG. 9A to FIG. 9C are diagrams illustrating operation examples.

FIG. 10A and FIG. 10B are diagrams illustrating a structure example of a display apparatus.

FIG. 11 is a diagram illustrating a structure example of a display apparatus.

FIG. 12 is a diagram illustrating a structure example of a display apparatus.

FIG. 13A to FIG. 13C are diagrams illustrating a structure example of a display apparatus.

FIG. 14A to FIG. 14F are diagrams illustrating pixel structure examples.

FIG. 15 is a diagram illustrating a structure example of a display apparatus.

FIG. 16A and FIG. 16B are diagrams illustrating a structure example of a display apparatus.

FIG. 17 is a diagram illustrating a structure example of a display apparatus.

FIG. 18A to FIG. 18F are diagrams each illustrating a structure example of a light-emitting device.

FIG. 19A to FIG. 19C are diagrams each illustrating a structure example of a light-emitting device.

FIG. 20A and FIG. 20B are diagrams illustrating structure examples of a light-receiving device.

FIG. 20C to FIG. 20E are diagrams illustrating structure examples of a display apparatus.

FIG. 21A is a block diagram illustrating an example of a display panel. FIG. 21B to FIG. 21D are diagrams illustrating examples of a pixel circuit.

FIG. 22A to FIG. 22D are diagrams illustrating examples of transistors.

FIG. 23A to FIG. 23F are diagrams illustrating structure examples of electronic devices.

FIG. 24A to FIG. 24G are diagrams illustrating structure examples of electronic devices.

### MODE FOR CARRYING OUT THE INVENTION

Hereinafter, embodiments are described with reference to the drawings. Note that the embodiments can be implemented in many different modes, and it is readily understood by those skilled in the art that modes and details thereof can be changed in various ways without departing from the spirit and scope thereof. Thus, the present invention should not be interpreted as being limited to the following description of the embodiments.

Note that in structures of the invention described below, the same portions or portions having similar functions are denoted by the same reference numerals in different drawings, and the description thereof is not repeated. Furthermore, the same hatching pattern is used for the portions having similar functions, and the portions are not especially denoted by reference numerals in some cases.

Note that in each drawing described in this specification, the size, the layer thickness, or the region of each component is exaggerated for clarity in some cases. Therefore, they are not limited to the illustrated scale.

Note that in this specification and the like, the ordinal numbers such as “first” and “second” are used in order to avoid confusion among components and do not limit the number of components.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or a formation order) of a stacked body or the like is described, even in the case where a surface on which the stacked body is provided (e.g., a formation surface, a support surface, an adhesion surface, or a planar surface) is positioned above the stacked body in the drawings, the direction and the opposite direction are expressed using “under” and “over”, respectively, in some cases.

In this specification and the like, the term “film” and the term “layer” can be interchanged with each other. For example, in some cases, the term “conductive layer” and the term “insulating layer” can be interchanged with the term “conductive film” and the term “insulating film”, respectively.

In this specification and the like, a display panel that is one embodiment of a display apparatus has a function of displaying (outputting) an image or the like on (to) a display surface. Therefore, the display panel is one embodiment of an output device.

In this specification and the like, a structure in which a connector such as an FPC (Flexible Printed Circuit) or a TCP (Tape Carrier Package) is attached to a substrate of a display panel, or a structure in which an IC is mounted on the substrate by a COG (Chip On Glass) method or the like is referred to as a display panel module or a display module, or simply as a display panel or the like in some cases.

Note that in this specification and the like, a touch panel that is one embodiment of a display apparatus has a function of displaying an image or the like on a display surface and a function of a touch sensor capable of detecting the contact, press, approach, or the like of a sensing target such as a finger or a stylus with or to the display surface. Thus, the touch panel is one embodiment of an input/output device.

A touch panel can also be referred to as, for example, a display panel (or a display apparatus) with a touch sensor, or a display panel (or a display apparatus) having a touch sensor function. A touch panel can include a display panel and a touch sensor panel. Alternatively, a touch panel can have a function of a touch sensor in the display panel or on the surface of the display panel.

In this specification and the like, a structure in which a connector or an IC is mounted on a substrate of a touch panel is referred to as a touch panel module or a display module, or simply as a touch panel or the like in some cases.

### Embodiment 1

In this embodiment, an image processing system of one embodiment of the present invention and an electronic device, a display apparatus, a server, and the like usable for the image processing system are described.

The image processing system of one embodiment of the present invention performs image processing in accordance with input from a user and can thereby reduce power consumption for image display. Furthermore, the image processing system performs part of processing on a server, eliminating the need for advanced arithmetic processing in an electronic device used by the user; thus, the image processing system can be achieved even with an inexpensive electronic device.

The image processing system of one embodiment of the present invention can be applied to an electronic device that includes a touch panel, for example. Such an electronic device can perform switching, scrolling, and the like of the screen in accordance with touch operation by the user. Similar operation can also be performed by an electronic device that includes not only the touch panel but also various input means (also referred to as user interfaces) such as a digitizer, a mouse, a touch pad, a controller, and a keyboard.

When the screen changes in accordance with the user's operation, an image displayed on the screen often includes both a portion with motion (referred to as a moving image portion) and a portion without motion (a still image portion). Here, in the moving image portion, the user is less likely to recognize the resolution of a faster-moving image; thus, reducing the resolution of the image in the moving image portion does not cause the user to have a feeling of strangeness. Therefore, when the moving image portion is subjected to image processing for reducing the resolution and the still image portion performs display with the original resolution, the amount of data in the whole image can be reduced. Furthermore, power consumption for image display and the arithmetic operation amount required for image processing (e.g., rendering) can be reduced.

The image processing system of one embodiment of the present invention can divide the whole image into two or more regions in accordance with the user's operation (pointing operation) and a displayed image and perform image processing for each region. Examples of the image processing include processing for reducing the resolution, processing for reducing the frequency, and processing for reducing the gray level (luminance).

The above image processing can also be performed in accordance with the user's gaze point. For example, the image processing can be performed such that the resolution, the frequency, or the gray level (luminance) is the highest at and in the vicinity of the gaze point and the resolution is lower in a portion farther from the gaze point.

When the image processing is performed in accordance with the user's gaze point, it is preferable to estimate the gaze point and define a region where the image processing is to be performed, in accordance with the position pointed by the user. For example, the region that includes the pointed position can be the region that includes the gaze point, and the image processing can be performed such that the resolution, the frequency, or the gray level (luminance) is lower in a portion farther from the pointed position.

More specific examples will be described below with reference to drawings.

### Structure Example

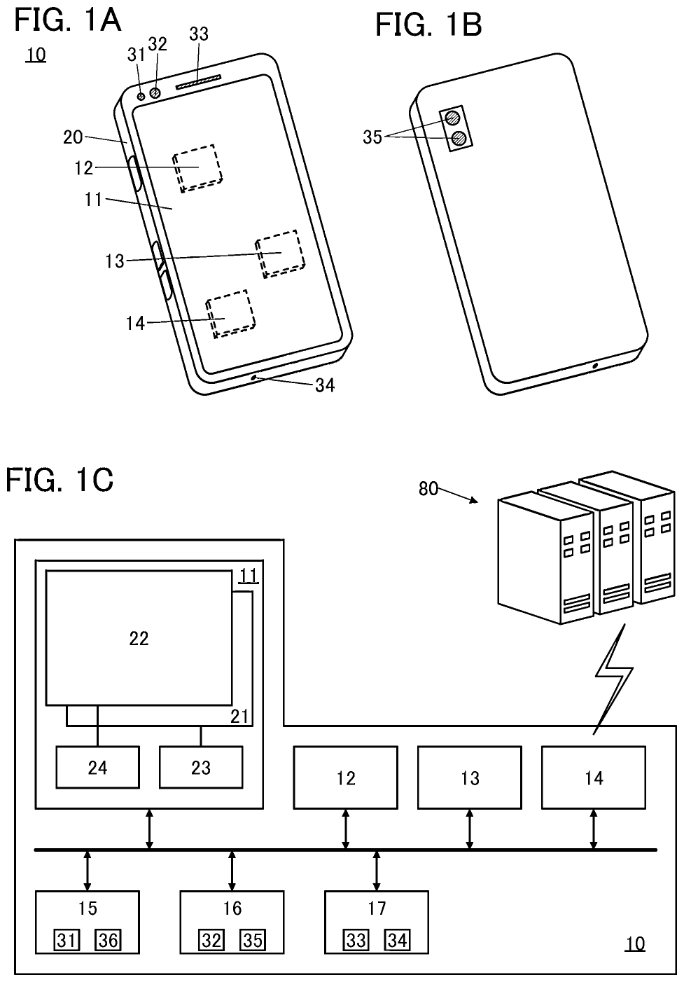

FIG. 1A and FIG. 1B are external views of an electronic device 10. FIG. 1A illustrates the front side of the electronic device 10, and FIG. 1B illustrates the rear side thereof.

The electronic device 10 is a portable information terminal that can be used as a smartphone or a tablet terminal. The electronic device 10 includes a display portion 11, an arithmetic portion 12, an image processing portion 13, a communication portion 14, and the like provided in a housing 20. FIG. 1A and FIG. 1B also illustrate an illuminance sensor 31, a camera 32, a speaker 33, a microphone 34, cameras 35, and the like included in the electronic device 10. Note that one embodiment of the present invention is not limited to this structure, and the electronic device 10 may include other components.

FIG. 1C is a block diagram illustrating an example of a hardware structure of part of the electronic device 10. The electronic device 10 includes the display portion 11, the arithmetic portion 12, the image processing portion 13, the communication portion 14, a sensor portion 15, an image capturing portion 16, an audio control portion 17, and the like. The components are electrically connected to one another via a bus line.

Hereinafter, for simple description, in the case where constituent elements other than the arithmetic portion 12 included in the electronic device 10 are not distinguished from one another, they are referred to as components in some cases, for example.

The display portion 11 includes a display apparatus 21 and an input device 22. The display portion 11 includes a driver portion 23 for controlling driving of the display apparatus 21 and a driver portion 24 for controlling driving of the input device 22. The driver portion 24 has a function of generating positional information from a signal output from the input device 22 and outputting the positional information. The display apparatus 21 has a function of displaying an image. The input device 22 has a function of a touch sensor. The display portion 11 can also be referred to as a touch panel or a display apparatus with a touch function.

The display apparatus 21 includes a plurality of pixel circuits arranged periodically. One or more display elements are connected to one pixel circuit. Examples of the display element include a liquid crystal element, an organic EL element, an inorganic EL element, an LED element, a microcapsule, an electrophoretic element, an electrowetting element, an electrofluidic element, an electrochromic element, and a MEMS element. It is particularly preferable to use an organic EL element, an LED element, or a liquid crystal element.

The size of the display portion 11 being equal, the display apparatus 21 having higher pixel density (also referred to as definition) can display an image with higher resolution. The pixel density (definition) of the display apparatus 21 is preferably higher than or equal to 50 ppi and lower than or equal to 1500 ppi, further preferably higher than or equal to 80 ppi and lower than or equal to 1200 ppi, still further preferably higher than or equal to 100 ppi and lower than or equal to 1000 ppi. Note that the definition of the display apparatus 21 is not limited thereto; the display apparatus 21 can have any of a variety of definitions in accordance with the application of the electronic device 10 and the size of the display portion 11.

The input device 22 has a function of obtaining the position pointed by the user and outputting the positional information to the arithmetic portion 12.

As the input device 22, a touch sensor is not necessarily used but any of the above-described various input means can be used. In the case where a sensor other than a touch sensor is used, the input device 22 may be provided independently instead of being included in the display portion 11.

The arithmetic portion 12 can function as, for example, a central processing unit (CPU). The arithmetic portion 12 has a function of controlling the components.

The arithmetic portion 12 can perform various types of arithmetic processing. For example, in accordance with the positional information input from the input device 22, the arithmetic portion 12 can perform arithmetic operation relating to division into a region where image processing is performed, a region where image processing is not performed, and the like.

The image processing portion 13 is controlled by the arithmetic portion 12 and has a function of performing image processing. The image processing portion 13 performs image processing on a plurality of regions obtained by the division by the arithmetic portion 12, for example, and generates an image to be displayed on the display portion 11. As the image processing portion 13, a processor such as a GPU (Graphics Processing Unit) is preferably used, for example. Although the image processing portion 13 is shown here as a component different from the arithmetic portion 12, the image processing portion 13 and the arithmetic portion 12 may share the same hardware.

The communication portion 14 is controlled by the arithmetic portion 12 and has a function of performing wireless communication or wired communication. The communication portion 14 can communicate with a server 80 provided outside the electronic device 10.

Here, a variety of sensors included in the electronic device 10 are collectively shown as the sensor portion 15. The sensor portion 15 includes an acceleration sensor 36 and the like in addition to the illuminance sensor 31 illustrated in FIG. 1A, for example. In the sensor portion 15, any of various sensors can be employed in accordance with the structure and required functions of the electronic device 10. For example, in addition to the aforementioned sensors, any of a variety of sensors such as a fingerprint sensor, a temperature sensor, a humidity sensor, a brain wave sensor, a blood pressure sensor, a geomagnetism sensor, and the GPS can be used.

A plurality of image capturing devices included in the electronic device 10 are collectively shown as the image capturing portion 16. The image capturing portion 16 includes the camera 32 and the cameras 35 illustrated in FIG. 1A, for example.

The electronic device 10 may have a function of estimating the user's gaze point with the use of the image capturing portion 16. For example, the camera 32 obtains information on the user's face and information on the distance between the electronic device 10 and the user. The arithmetic portion 12 can estimate the user's gaze point on the screen of the display portion 11 from the positions of the two eyeballs that can be obtained from the information on the user's face, the distance between the electronic device 10 and the user, and the like.

The arithmetic portion 12 may have a function of executing face authentication. For example, the arithmetic portion 12 can execute face authentication by using the feature points obtained from an image of the user's face captured with the camera 32. Specifically, in the case where the camera 32 is used for face authentication, it is preferable that a camera having sensitivity to infrared light as well as visible light be used or both a camera having sensitivity to visible light and a camera having sensitivity to infrared light be provided.

The two cameras 35 are provided on the rear surface of the electronic device 10 in the example illustrated in FIG. 1B; providing a plurality of cameras having different field angles makes it possible to cover a variety of focal lengths, i.e., cover various fields of view ranging from a wide field of view to a telescope field of view. With the use of images that are captured at the same time by a plurality of cameras, focus and a depth of field can be changed with the use of the image after the image capturing. Furthermore, a camera having sensitivity to infrared light or ultraviolet light may be provided.

The audio control portion 17 has a function of controlling audio output and audio input. The audio control portion 17 includes the speaker 33 and the microphone 34 illustrated in FIG. 1A, for example. As audio output devices included in the audio control portion 17, not only the speaker but also a built-in speaker such as a bone-conduction speaker may be used. Audio data may be output to earphones, headphones, an external speaker, or the like with or without a wire.

Signals are transmitted between the arithmetic portion 12 and the components via the bus line. The arithmetic portion 12 has a function of processing signals input from the components connected via the bus line, a function of generating signals to be output to the components, and the like, so that the components connected to the bus line can be controlled comprehensively.

Note that a transistor that includes an oxide semiconductor in a channel formation region and that achieves an extremely low off-state current can be used in an IC or the like included in the arithmetic portion 12 or another component. The transistor has an extremely low off-state current; therefore, with the use of the transistor as a switch for retaining electric charge (data) that flows into a capacitor functioning as a storage element, a long data retention period can be ensured. By utilizing this characteristic for a register, a cache memory, or the like of the arithmetic portion 12 or the image processing portion 13, normally-off computing is achieved where the arithmetic portion 12 or the like operates only when needed, and otherwise power supply to the arithmetic portion 12 or the like is stopped after information on the previous processing is stored in the storage element when the arithmetic portion 12 is not used; thus, power consumption of the electronic device 10 can be reduced.

The arithmetic portion 12 interprets and executes instructions from various programs with a processor to process various kinds of data and control programs. Programs that might be executed by the processor may be stored in a memory region of the processor or may be stored in another storage portion.

A CPU and other microprocessors such as a DSP (Digital Signal Processor) and a GPU (Graphics Processing Unit) can be used alone or in combination as the arithmetic portion 12 and the image processing portion 13. A structure may be employed in which such a microprocessor is obtained with a PLD (Programmable Logic Device) such as an FPGA (Field Programmable Gate Array) or an FPAA (Field Programmable Analog Array).

The arithmetic portion 12 and the image processing portion 13 may each include a main memory. The main memory can include a volatile memory such as a RAM (Random Access Memory) or a nonvolatile memory such as a ROM (Read Only Memory).

For example, a DRAM (Dynamic Random Access Memory) is used for the RAM provided in the main memory, in which case a memory space as a workspace for the arithmetic portion 12 or the image processing portion 13 is virtually allocated and used. An operating system, an application program, a program module, program data, and the like that are stored in the storage portion are loaded into the RAM to be executed. The data, program, program module, and the like that are loaded into the RAM are directly accessed and operated by the arithmetic portion 12 or the image processing portion 13.

Meanwhile, a BIOS (Basic Input/Output System), firmware, and the like for which rewriting is not needed can be stored in the ROM. As the ROM, a mask ROM, an OTPROM (One Time Programmable Read Only Memory), an EPROM (Erasable Programmable Read Only Memory), or the like can be used. Examples of the EPROM include a UV-EPROM (Ultra-Violet Erasable Programmable Read Only Memory) which can erase stored data by ultraviolet irradiation, an EEPROM (Electrically Erasable Programmable Read Only Memory), and a flash memory.

The image processing portion 13 preferably includes a processor specialized for parallel arithmetic operation as compared with a CPU. For example, a processor that includes a large number of (several tens to several hundreds of) processor cores capable of performing parallel processing, such as a GPU, a TPU (Tensor Processing Unit), or an NPU (Neural Processing Unit), is preferably included. In that case, the image processing portion 13 can especially perform arithmetic operation by a neural network at high speed.

The communication portion 14 can transmit and receive data to and from an external communication device wirelessly. The communication portion 14 can perform communication via an antenna, for example. As the communication means (communication method) of the communication portion 14, for example, a computer network such as the Internet, which is the infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network) can be used. For wireless communication, it is possible to use, as a communication protocol or a communication technology, a communication standard such as the third-generation mobile communication system (3G), the fourth-generation mobile communication system (4G), or the fifth-generation mobile communication system (5G), or a communication standard developed by IEEE such as Wi-Fi (registered trademark) or Bluetooth (registered trademark).

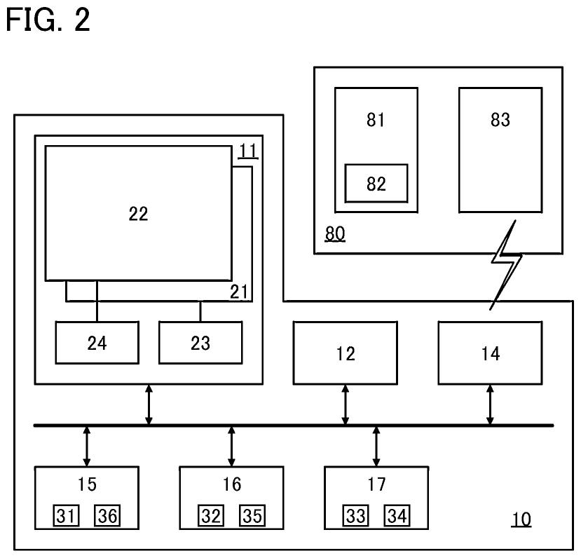

FIG. 2 illustrates an example of changing part of the above-described structure. FIG. 2 also includes a block diagram of the server 80.

The server 80 includes an arithmetic portion 81, an image processing portion 82, and a communication portion 83.

For the arithmetic portion 81, the description of the arithmetic portion 12 can be referred to. Here, an example in which the arithmetic portion 81 includes the image processing portion 82 is described. That is, the arithmetic portion 81 can execute image processing.

Meanwhile, the electronic device 10 illustrated in FIG. 2 does not include the image processing portion 13. The arithmetic operation for image processing that would be performed by the image processing portion 13 can be executed in the image processing portion 82 of the server 80 through the communication portion 14 and the communication portion 83.

When the electronic device 10 and the server 80 are connected through the communication portions and part of arithmetic processing is executed on the server 80 side as described above, high arithmetic capacity is not required on the electronic device 10 side; thus, components can be simplified. Accordingly, not only can the cost of the electronic device 10 be reduced, but also the weight, size, and thickness of the electronic device 10 can be easily reduced. Such a system in which the bulk of processing is performed by a server and a terminal can have a simplified structure can be referred to as a thin client system.

Furthermore, part of the processing that would be executed by the arithmetic portion 12 can be executed by the arithmetic portion 81 of the server 80. For example, processing relating to the aforementioned division can be executed on the server 80 side.

In recent years, such a thin client in which main arithmetic processing is executed on a server side and only limited processing is performed on a client side has been attracting attention. As execution methods for a thin client, a network boot method, a server base method, a blade PC method, a virtual desktop infrastructure (VDI) method, and the like have been proposed.

### [Method for Driving Image Processing System]

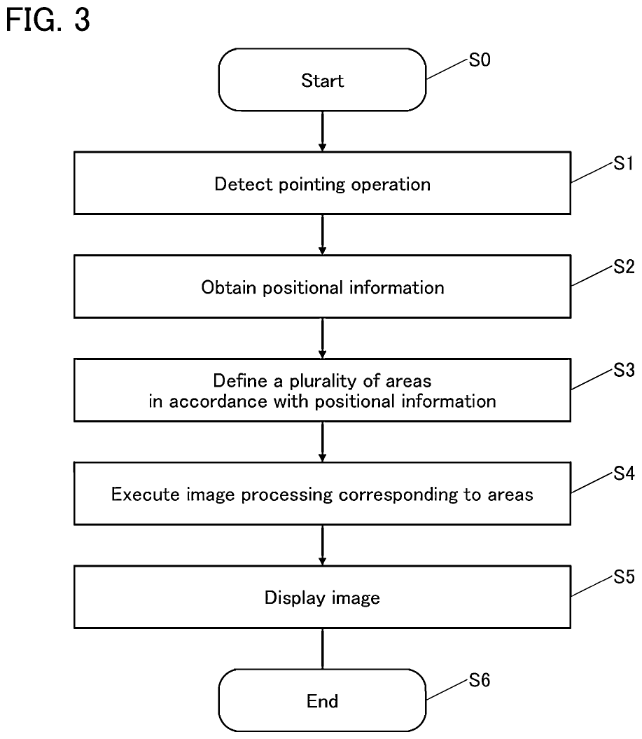

Next, an example of a method for driving an image processing system that can be achieved by the electronic device 10 or the electronic device 10 and the server 80 is described. FIG. 3 is a flow chart of an example of a method for driving an image processing system. The flow chart in FIG. 3 includes Step S0 to Step S6.

In Step S0, processing starts. In Step S0, the electronic device 10 is usable.

In Step S1, the input device 22 detects pointing operation by the user. For example, in the case where the electronic device 10 includes a touch panel, touch operation (e.g., tapping or swiping) by the user corresponds to the pointing operation. In the case where a mouse is used as an input means, operation (e.g., moving, clicking, or double-clicking) of the mouse by the user corresponds to the pointing operation.

In Step S2, the arithmetic portion 12 obtains positional information from the input device 22 and the driver portion 24. In the case of a touch panel, the coordinates of a touched position correspond to the positional information. In the case where a mouse or the like is used, the coordinates of the position pointed by a cursor correspond to the positional information.

In Step S3, the arithmetic portion 12 executes processing for defining a plurality of areas (regions) in accordance with the above positional information (this processing is also referred to as dividing processing). In the dividing processing, the whole region of the display portion is divided into a plurality of regions in accordance with the positional information, and the results are output as area information. In the dividing processing, division may be performed in accordance with both the positional information and information on an image. The area information output by the arithmetic portion 12 is used for the subsequent image processing executed by the image processing portion 13.

Here, the processing in Step S3 may be executed by the arithmetic portion 81 in the server 80. In that case, a step of transmitting the positional information and the information on the image to the server 80 is added between Step S2 and Step S3.

In Step S4, the image processing portion 13 executes image processing corresponding to an area of an original image (a first image) in accordance with the area information generated by the above dividing processing, and generates an image after the image processing (a second image). Note that no image processing may be performed in some areas, in which case the original image remains in the areas. For example, in the case of division into two areas, image processing is performed on one area or different types of image processing are performed on the two areas. In the case of division into three or more areas, different types of image processing are performed on two areas or different types of image processing are performed on three areas.

The image processing can be processing for reducing the resolution (also referred to as down-conversion or downscaling), for example. For example, it is possible to employ a method in which n×n pixels (n is an integer greater than or equal to 2) have the same pixel value. The pixel value can be determined by the average value, the median value, the weighted average, the Gaussian distribution, or the like. The down-conversion is not necessarily performed by this method but can be performed by any of a variety of methods.

As the image processing, processing for increasing the resolution (also referred to as up-conversion or upscaling) may be performed. For example, a portion the user is gazing at can be displayed with resolution higher than that of the portion in the original image.

The image processing can be processing for reducing the gray level (reducing the luminance) or processing for increasing the gray level (increasing the luminance). The image processing may be processing for increasing or reducing the driving frequency (frame frequency).

A reduction in the driving frequency can result in a reduction in power consumption of the electronic device 10. On the other hand, a reduction in the driving frequency causes a reduction in display quality. In particular, the display quality in displaying a moving image is reduced. For example, when the driving frequency in a region where the visibility by the user is low is reduced, a reduction in the practical display quality can be inhibited while power consumption is reduced. According to one embodiment of the present invention, both display quality maintenance and a reduction in power consumption can be achieved.

For example, in a region where display is performed with a high driving frequency (a first driving frequency), the first driving frequency is higher than or equal to 30 Hz and lower than or equal to 500 Hz, preferably higher than or equal to 60 Hz and lower than or equal to 400 Hz. By contrast, in a region where display is performed with a low driving frequency (a second driving frequency), the second driving frequency is preferably lower than or equal to ½ of the first driving frequency, further preferably lower than or equal to ⅕ of the first driving frequency. By reducing the driving frequency and significantly reducing image rewriting frequency, power consumption can be further reduced. Note that rewriting of image data may be stopped if necessary. By stopping rewriting of image data, power consumption can be further reduced.

In the case where such a driving method is employed, a transistor with an extremely low off-state current is suitably used as a transistor included in the pixel circuit of the display apparatus 21. For example, a transistor that includes an oxide semiconductor in a semiconductor where a channel is formed (an OS transistor) is suitably used as the transistor included in the pixel circuit. An OS transistor has an extremely low off-state current and thus enables long-term retention of image data supplied to the pixel circuit.

Note that the processing in Step S4 may be executed by the image processing portion 82 in the server 80. In that case, a step of transmitting the aforementioned area information and the first image to the server 80 is added between Step S3 and Step S4.

Note that both the processing in Step S3 and that in Step S4 may be performed in the server 80.

In Step S5, the display portion 11 displays the second image.

In Step S6, the processing ends.

### Image Display Example 1

Next, examples of an image displayed using the image processing system of one embodiment of the present invention are described. Here, the cases of an electronic device that includes a touch panel is described.

### Display Example 1-1

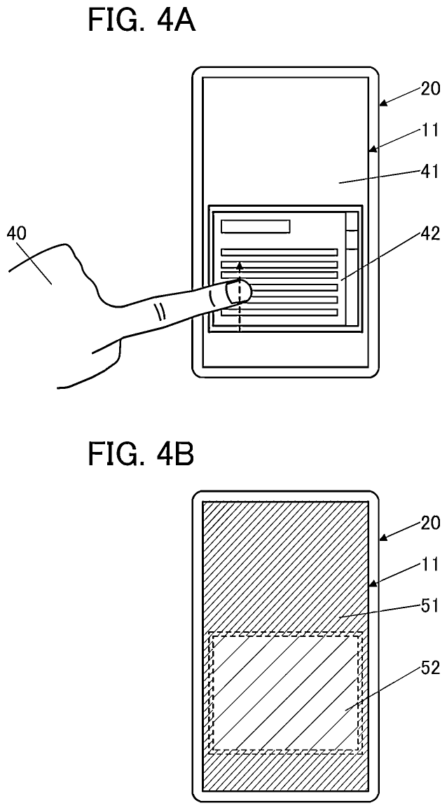

In FIG. 4A, the display portion 11 displays an image 41 that is a background and an image 42 that contains character information. Furthermore, FIG. 4A illustrates a state where the character information is scrolled upward by swipe operation performed on a portion of the image 42 with a finger of a user 40.

FIG. 4B illustrates examples of divided areas for the images displayed in FIG. 4A. A region 52 corresponds to a region where the image 42 is displayed. A region 51 corresponds to a region where the image 41 is displayed. Here, the region 51 and the region 52 are denoted with different hatching patterns to be distinguished from each other. In the region 52, a moving image in which the character information moves upward is displayed and thus, a reduction in one or both of the resolution and the frame frequency does not give a feeling of strangeness. Thus, the region 52 is subjected to image processing for reducing one or both of the resolution and the frame frequency. Meanwhile, the region 51 is not subjected to such image processing.

A higher frame frequency enables displaying a smoother moving image; thus, image processing for increasing the frame frequency may be performed in the case of a fast moving image or the like. For example, in the case where 60-Hz display is normally performed, 90-Hz or 120-Hz display can be performed in a region where a moving image is displayed.

Although FIG. 4B illustrates an example case of pixel-wise setting of areas such that the shapes of the divided areas are substantially the same as those of the displayed images, the dividing positions of areas may be defined in advance. In that case, arithmetic processing for division into areas can be more easily performed.

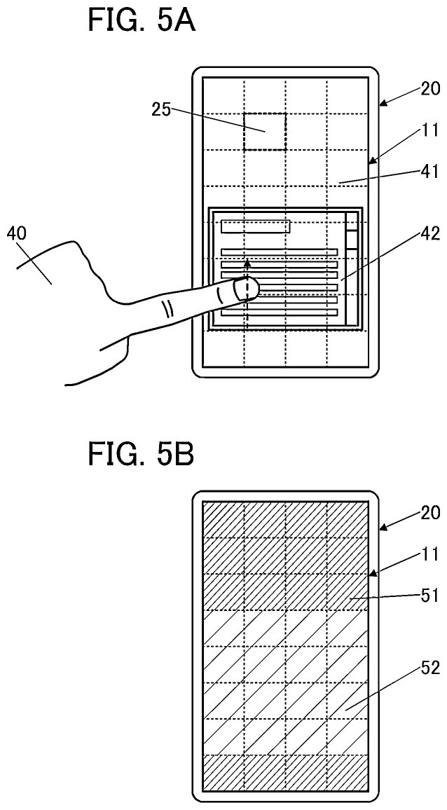

FIG. 5A illustrates an example case where the display portion 11 is divided into a plurality of areas 25 in advance. Here, the display portion 11 is divided into 4×8 (32) areas 25.

Although the boundaries between the areas are indicated by dashed lines in FIG. 5A, no boundary lines are actually displayed.

FIG. 5B illustrates example divided areas. The region 52 corresponds to 4×4 areas that include a region where the image 42 is displayed. The region 51 corresponds to the other 16 areas. The display portion 11 is divided into 4×8 areas in this example case; a larger division number enables displaying a more natural image. By contrast, a smaller division number enables reducing the load of arithmetic processing.

### Display Example 1-2

An example case where image processing is performed in accordance with a pointed position is described below.

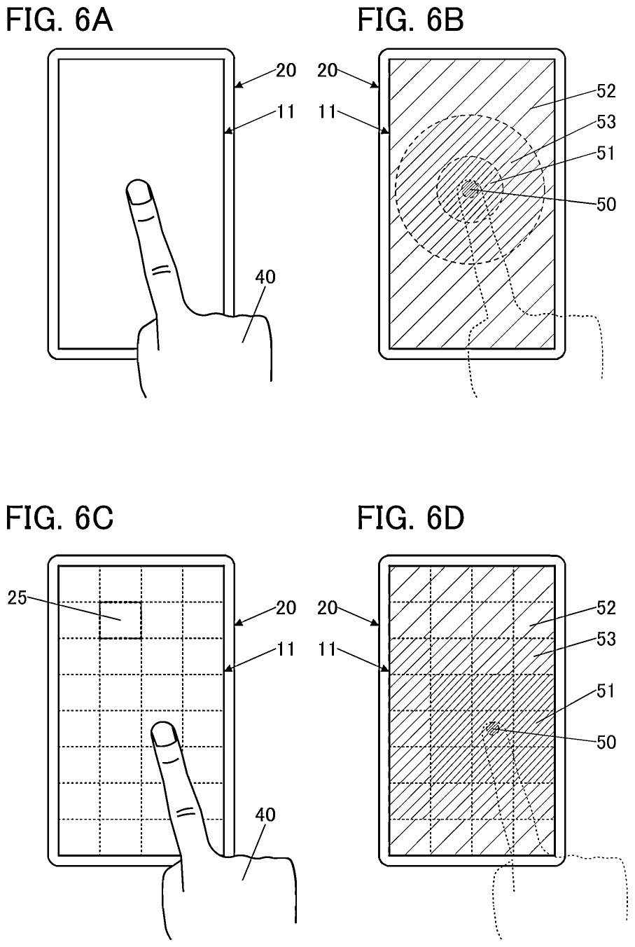

FIG. 6A illustrates a state where a finger of the user 40 touches (taps) the display portion 11. FIG. 6B illustrates example divided areas in this state.

As illustrated in FIG. 6B, the display portion 11 is divided into the region 51 concentric with a contact position 50 of the finger of the user 40, a region 53 having a larger diameter than the region 51, and the region 52 located outside the region 53.

In many cases, when the user 40 taps the display portion 11, the user 40 gazes at the vicinity of the contact position 50. In view of this, display is performed with the highest resolution and the highest frame frequency in the region 51 that includes the contact position 50, and display is performed with the lowest resolution or the lowest frame frequency in the region 52 farthest from the contact position 50. In the region 53 located between the region 51 and the region 52, display can be performed with resolution and a frame frequency that are lower than or equal to those in the region 51 and higher than or equal to those in the region 52. Although an example of division into three kinds of regions is described here, division into four or more kinds of regions may be employed. The size of each region is preferably determined in advance in consideration of the characteristics of the human visual field. Note that the size of each region may be changed whenever necessary in accordance with the distance between the eyes of the user 40 and the display portion 11.

In general, the human visual field is roughly classified into the following five fields, although varying between individuals. The discrimination visual field refers to a region within approximately 5° from the center of vision including the gaze point, where visual performance such as eyesight and color identification is the most excellent. The effective visual field refers to a region that is horizontally within approximately 30° and vertically within approximately 20° from the center of vision (gaze point) and adjacent to the outside of the discrimination visual field, where instant identification of particular information is possible only with an eye movement. The stable visual field refers to a region that is horizontally within approximately 90° and vertically within approximately 70° from the center of vision and adjacent to the outside of the effective visual field, where identification of particular information is possible without any difficulty with a head movement. The inducting visual field refers to a region that is horizontally within approximately 100° and vertically within approximately 85° from the center of vision and adjacent to the outside of the stable visual field, where the existence of a particular target can be sensed but the identification ability is low. The supplementary visual field refers to a region that is horizontally within approximately 100° to 200° and vertically within approximately 85° to 130° from the center of vision and adjacent to the outside of the inducting visual field, where the identification ability for a particular target is significantly low to an extent that the existence of a stimulus can be sensed.

As compared to the resolution of an image displayed in a region that includes a gaze point, the resolution of an image displayed in the other regions is set low in this manner, reducing the load during video signal generation (rendering). Such processing is also referred to as “foveated rendering”. When foveated rendering is combined with a reduction in driving frequency of the regions other than the region that includes the gaze point, power consumption can be further reduced while a reduction in display quality is inhibited.

FIG. 6C and FIG. 6D illustrate an example case where the display portion 11 is divided in advance.

Here, in the case where the display portion 11 includes an optical sensor, the shape and positional information of an obstacle (e.g., part of the hand) present between the screen and the eyes of the user 40 can be obtained. The user does not see a portion of the display portion 11 that is hidden behind the obstacle, i.e., a region of the display portion 11 on which the shadow of the obstacle is cast; thus, light can be off in this region.

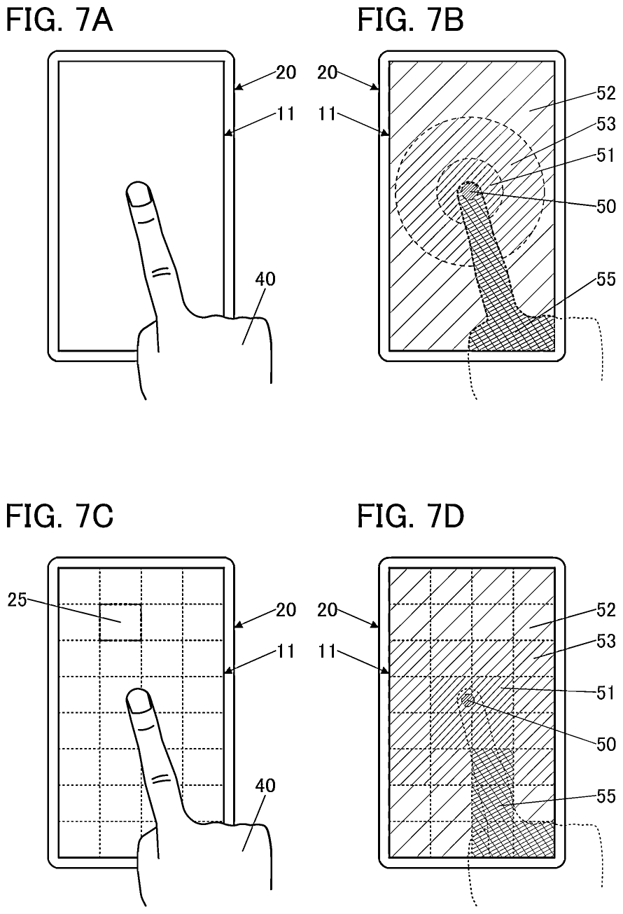

FIG. 7A and FIG. 7B illustrate a state where a finger of the user 40 taps the display portion 11 as in FIG. 6A. As illustrated in FIG. 7B, display is not performed (i.e., black display is performed) in a region 55 hidden behind the finger and part of the hand of the user 40. By the above-described driving such that the light is off in the region not seen by the user 40, power consumption can be reduced more effectively.

FIG. 7C and FIG. 7D illustrate an example case where the display portion 11 is divided in advance. Here, the user 40 might see part of a region in which the light is off. Thus, it is preferable that the user 40 be allowed to freely set whether to use the function of turning off the light in a region of the display portion 11 that is not seen.

### Image Display Example 2

Example cases where not a touch panel but an input means such as a mouse is used are described below.

### Display Example 2-1

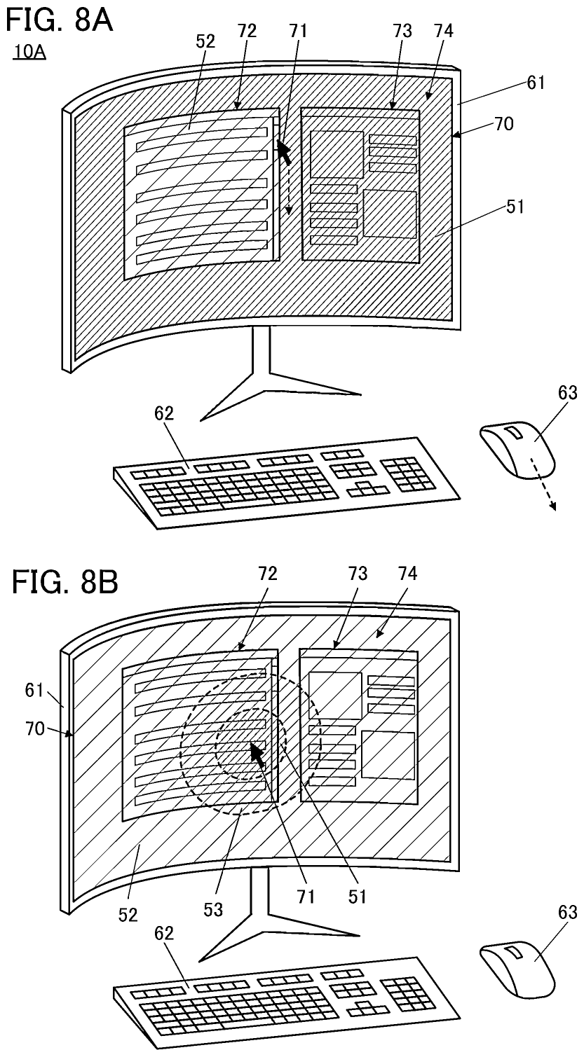

An electronic device 10A illustrated in FIG. 8A includes a main body 61 as well as a keyboard 62 and a mouse 63 as input means. Note that one or more input means are provided. In the case where the keyboard 62 includes a touch pad, for example, the mouse 63 is not needed.

The main body 61 includes a display portion 70. The display portion 70 may have a function of a touch panel. Although not shown, the main body 61 includes at least the arithmetic portion 12, the image processing portion 13, and the communication portion 14 in a position overlapping with the display portion 70. The sensor portion 15, the image capturing portion 16, the audio control portion 17, and the like may also be included.

The electronic device 10A has what is called a multitasking function, which can execute a plurality of applications programs at one time. In this example, the display portion 70 displays a cursor 71, a window 72, a window 73, and a background 74. The window 72 and the window 73 deal with different tasks and display different images.

FIG. 8A illustrates a state where a scroll bar displayed in the window 72 is operated to scroll the contents displayed in the window 72. At this time, the region where the window 72 is displayed is the region 52, and the other region (the region where the window 73 and the background 74 are displayed) is the region 51. The image displayed in the region 52 has lower resolution than the image displayed in the region 51. The image in the region 52 may be displayed with a lower frequency or lower luminance than the image in the region 51.

### Display Example 2-2

FIG. 8B illustrates an example of division into a plurality of concentric regions centered at the cursor 71. In a period during which the user operates the mouse 63, the user gazes at the cursor 71 or the vicinity thereof in many cases. Thus, when display is performed with high resolution at the cursor 71 or the vicinity thereof and display is performed with lower resolution in a portion farther from the cursor 71, power consumption can be reduced without causing the user to have a feeling of strangeness.

In FIG. 8B, display is performed with the highest resolution and the highest frame frequency in the region 51 that includes the cursor 71, and display is performed with the lowest resolution or the lowest frame frequency in the region 52 farthest from the cursor 71 as in FIG. 6A. In the region 53 between the region 51 and the region 52, display is performed with resolution and a frame frequency that are lower than or equal to those in the region 51 and higher than or equal to those in the region 52.

### Display Example 2-3

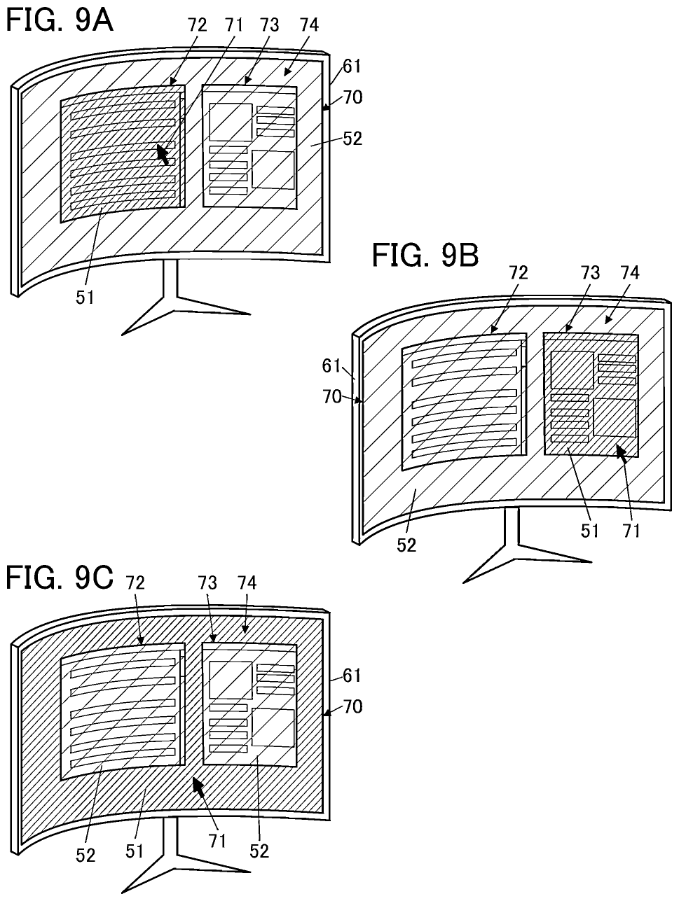

FIG. 9A to FIG. 9C illustrate an example case where division into regions is performed in accordance with the position of the cursor 71 and a displayed image.

In a period during which the user operates the mouse 63, the user puts the cursor 71 on a working window in many cases; thus, it is possible to estimate that the user is gazing at the window 72 overlapping with the cursor 71. Accordingly, in FIG. 9A, the whole window 72 overlapping with the cursor 71 is the region 51 where display is performed with the highest resolution and the highest frame frequency, and the others, i.e., the window 73 and the background 74, are the region 52 where display is performed with the lowest resolution or the lowest frame frequency. FIG. 9B illustrates an example case where the window 72 overlapping with the cursor 71 is the region 51.

As illustrated in FIG. 9C, in the case where the cursor 71 does not overlap with any window but overlaps with the background 74, the background 74 can be the region 51 where display is performed with the highest resolution and the highest frame frequency, and the window 72 and the window 73 can be the regions 52 where display is performed with the lowest resolution or the lowest frame frequency.

Power consumption can be effectively reduced by making higher the resolution of a working region (window) where the cursor is positioned and lower the resolution of the other regions as described above.

Note that image processing may be performed to reduce the resolution to the extent that the user notices the reduction. That is, clear display can be performed in a region where the electronic device 10A recognizes as a working area, whereas display can be blurred in the other regions. In that case, the user can know which area the electronic device 10A recognizes as a working region, enhancing working efficiency.

After a window is once made active by mouse operation or the like, the window may be displayed with high resolution and a high frame frequency in a period during which the active state is maintained, whereas the other regions may be displayed with lower resolution and a lower frame frequency. In that case, power consumption can be reduced without causing the user to have a feeling of strangeness even when the user's operation is switched from mouse operation to keyboard operation.

At least part of this embodiment can be implemented in combination with the other embodiments described in this specification as appropriate.

### Embodiment 2

A structure example of a display apparatus that can be used for the image processing system of one embodiment of the present invention will be described below.

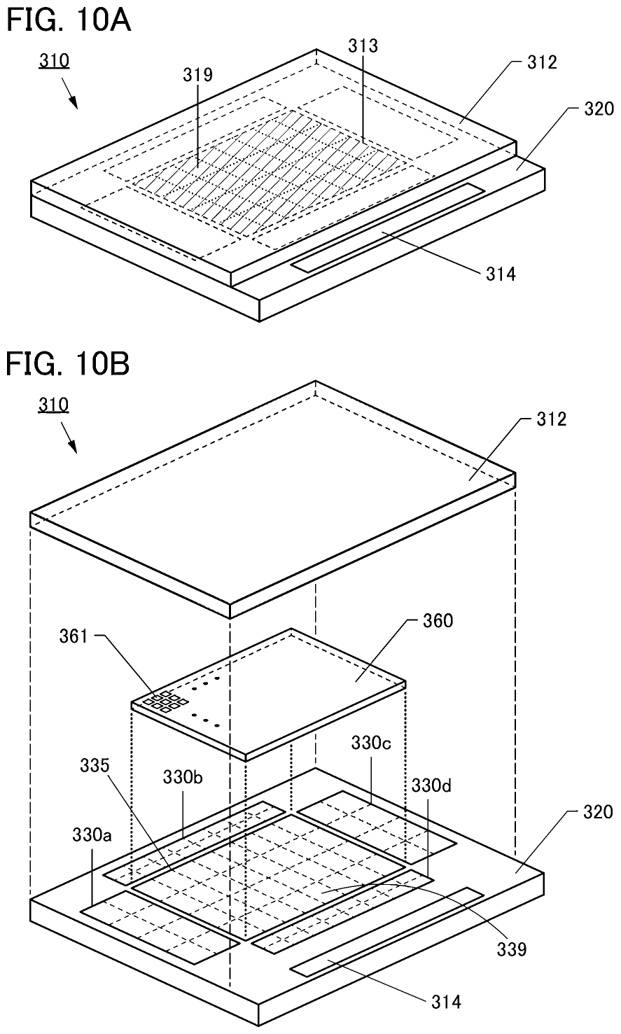

FIG. 10A and FIG. 10B are perspective views of a display apparatus 310. The perspective view in FIG. 10B illustrates structures of layers included in the display apparatus 310.

The display apparatus 310 includes a substrate 320 and a substrate 312. The display apparatus 310 includes a display portion 313 provided between the substrate 320 and the substrate 312. The display portion 313 includes a plurality of sub-display portions 319. A layer 360 is provided between the substrate 320 and the substrate 312. The substrate 312 is preferably a light-transmitting substrate or a layer formed of a light-transmitting material.

The layer 360 includes a plurality of light-emitting elements 361. The layer 360 can be stacked over the substrate 320. As the light-emitting element 361, an organic electroluminescent element (also referred to as an organic EL element) or the like can be used, for example. However, the light-emitting element 361 is not limited thereto, and an inorganic EL element formed of an inorganic material may be used, for example. Note that an “organic EL element” and an “inorganic EL element” are collectively referred to as “EL element” in some cases. The light-emitting element 361 may contain an inorganic compound such as quantum dots. For example, when used for a light-emitting layer, the quantum dots can function as a light-emitting material.

As illustrated in FIG. 10B, over the substrate 320, a pixel circuit group 335 that includes a plurality of pixel circuits, a driver circuit 330 (driver circuits 330a, 330b, 330c, and 330d), and a terminal portion 314 are provided in the same layer. Since the pixel circuit group 335 and the driver circuit 330 are provided in the same layer, wirings electrically connecting the circuits can be short. Thus, wiring resistance and parasitic capacitance are reduced, leading to lower power consumption.

Any of a variety of transistors such as a Poly-Si transistor and an OS transistor can be employed as a transistor used in the display apparatus 310, for example. Alternatively, both a Poly-Si transistor and an OS transistor can be used in the display apparatus 310. In that case, both a Poly-Si transistor and an OS transistor can be formed over the substrate 320.

Part or the whole of the driver circuit 330 can be formed using one or both of a transistor that includes polycrystalline silicon in a semiconductor where a channel is formed (Poly-Si transistor) and an OS transistor. Alternatively, an IC chip fabricated using a single crystal silicon substrate may be used for the driver circuit 330.

Note that in the case where the diagonal size of the display apparatus 310 is less than or equal to 3 inches or less than or equal to 2 inches, a transistor that includes single crystal silicon in a semiconductor where a channel is formed (c-Si transistor) can be employed as a transistor used in the display apparatus 310. When a single crystal silicon substrate is used as the substrate 320, the substrate 320 can be provided with the pixel circuit group 335, the driver circuit 330, and the terminal portion 314. In that case, the display apparatus 310 can be lightweight, the production cost thereof can be reduced, and the productivity thereof can be improved.

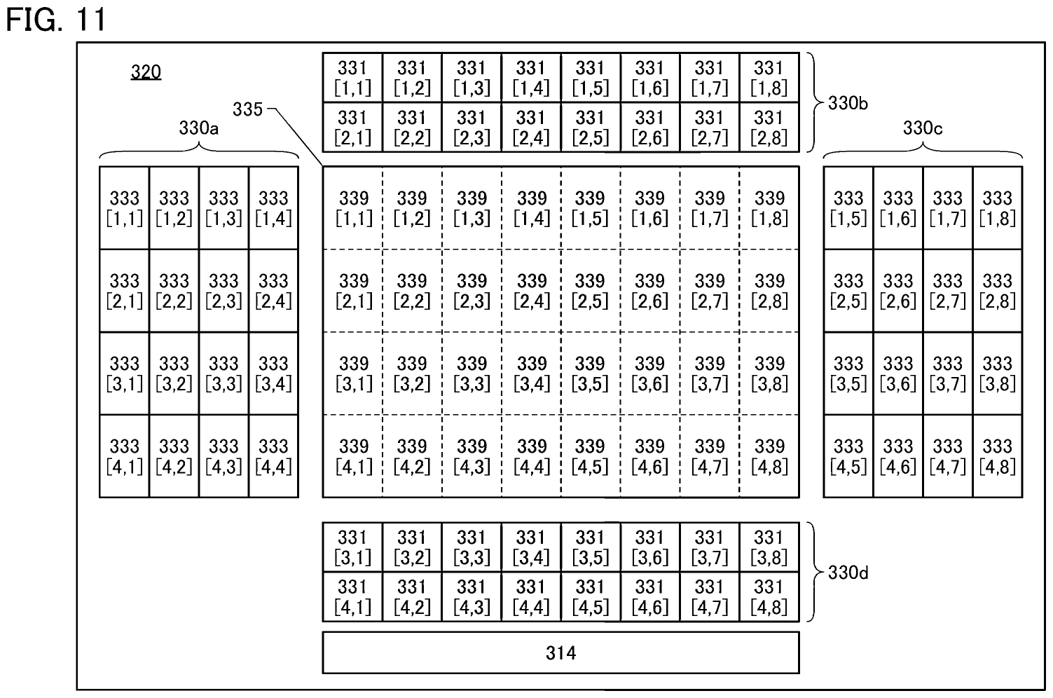

In the display apparatus 310 illustrated in FIG. 10A and FIG. 10B, the display portion 313 is composed of the sub-display portions 319 arranged in a matrix of m rows and n columns. Accordingly, the pixel circuit group 335 is divided into sections 339 arranged in a matrix of m rows and n columns. FIG. 11 illustrates a planar layout of the substrate 320. FIG. 11 illustrates the sections 339 of the case where m is 4 and n is 8.

The driver circuit 330 is provided in the display apparatus 310 as four divided regions: the driver circuit 330a, the driver circuit 330b, the driver circuit 330c, and the driver circuit 330d. The driver circuit 330a, the driver circuit 330b, the driver circuit 330c, and the driver circuit 330d are provided outside the pixel circuit group 335. Specifically, the driver circuit 330a is provided at a first side of the four sides of the outer periphery of the pixel circuit group 335, the driver circuit 330c is provided at a third side that faces the first side with the pixel circuit group 335 located therebetween, the driver circuit 330b is provided at a second side, and the driver circuit 330d is provided at a fourth side that faces the second side with the pixel circuit group 335 located therebetween.

The driver circuit 330a and the driver circuit 330c each include 16 gate driver circuits 333. The driver circuit 330b and the driver circuit 330d each include 16 source driver circuits 331. One of the gate driver circuits 333 is electrically connected to a plurality of pixel circuits included in one of the sections 339. One of the source driver circuits 331 is electrically connected to a plurality of pixel circuits included in one of the sections 339.

In FIG. 11, the gate driver circuit 333 electrically connected to a section 339 [i,j] (i is an integer greater than or equal to 1 and less than or equal to m and j is an integer greater than or equal to 1 and less than or equal to n) is denoted as a gate driver circuit 333 [i,j], and the source driver circuit 331 connected to the section 339 [i,j] is denoted as a source driver circuit 331 [i,j].

As illustrated in FIG. 11, the driver circuit 330a includes 16 of the gate driver circuits 333 in four columns (j=1 to 4), and the driver circuit 330c includes 16 of the gate driver circuits 333 in the other four columns (j=5 to 8). The driver circuit 330b includes 16 of the source driver circuits 331 in two rows (i=1 to 2), and the driver circuit 330d includes the source driver circuits 331 in the other two rows (i=3 to 4).

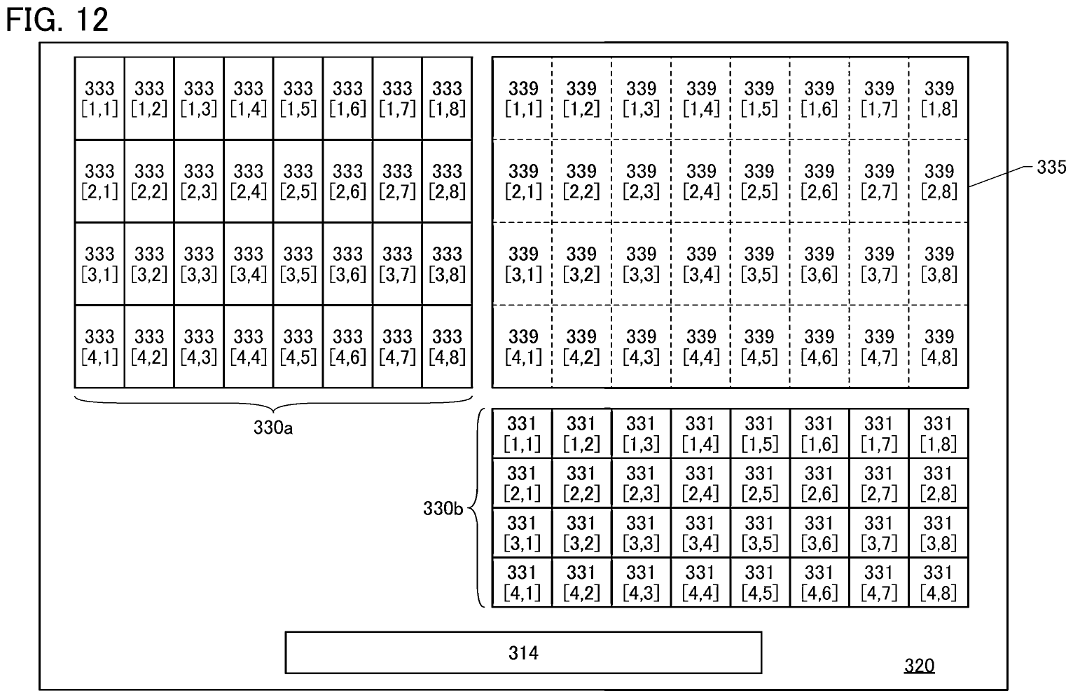

The positions of the pixel circuit group 335 and the driver circuit 330 provided over the substrate 320 are not limited to those illustrated in FIG. 11. For example, the structure illustrated in FIG. 12 may be employed. In FIG. 12, the driver circuit 330 is provided as two divided regions: the driver circuit 330a and the driver circuit 330b. For example, the driver circuit 330a includes 32 of the gate driver circuits 333 (a gate driver circuit 333 [1,1] to a gate driver circuit 333 [4,8]) and the driver circuit 330b includes 32 of the source driver circuits 331 (a source driver circuit 331 [1,1] to a source driver circuit 331 [4,8]).

Such a display apparatus 310 can be suitably used in the case of preliminary division into areas, which is described in Embodiment 1 with reference to FIG. 5A, FIG. 5B, and the like, for example. Although the case where the display portion 313 is divided into 32 of the sub-display portions 319 is described as an example here, the display portion 313 is not necessarily divided into 32 of the sub-display portions 319 but may be divided into 16 of the sub-display portions 319, 64 of the sub-display portions 319, 128 of the sub-display portions 319, 256 of the sub-display portions 319, 512 of the sub-display portions 319, or 1024 of the sub-display portions 319, for example. As the division number of the display portion 313 increases, a reduction in practical display quality perceived by the user can be smaller.

At least part of this embodiment can be implemented in combination with the other embodiments described in this specification as appropriate.

### Embodiment 3

In this embodiment, structure examples of a display apparatus that can be employed for the image processing system of one embodiment of the present invention will be described. A display apparatus described below can be employed for the display portion 11 or the display apparatus 21 in Embodiment 1.

One embodiment of the present invention is a display apparatus that includes a light-emitting element (also referred to as a light-emitting device). The display apparatus includes two or more light-emitting elements of different emission colors. The light-emitting elements each include a pair of electrodes and an EL layer therebetween. The light-emitting elements are preferably organic EL elements (organic electroluminescent elements). The two or more light-emitting elements of different emission colors include EL layers formed using different light-emitting materials. The display apparatus can perform full-color display by including three types of light-emitting elements that emit red (R) light, green (G) light, and blue (B) light, for example.

In the case of manufacturing a display apparatus that includes a plurality of light-emitting elements of different emission colors, layers (light-emitting layers) including at least light-emitting materials each need to be formed in an island shape. In a known method for separately forming part or the whole of an EL layer, an island-shaped organic film is formed by an evaporation method using a shadow mask such as a metal mask. However, this method has difficulty in achieving high definition and a high aperture ratio of a display apparatus because in this method, a deviation from the designed shape and position of the island-shaped organic film is caused by various influences such as the accuracy of the metal mask, the positional deviation between the metal mask and a substrate, a warp of the metal mask, and expansion of the outline of the formed film due to vapor scattering or the like. In addition, the outline of the layer might blur during evaporation, so that the thickness of an end portion might be reduced. That is, the thickness of an island-shaped light-emitting layer might vary from place to place. In addition, in the case of manufacturing a display apparatus with a large size, high resolution, or high definition, a manufacturing yield might be reduced because of low dimensional accuracy of the metal mask and deformation due to heat or the like. Thus, a measure has been taken for a pseudo increase in definition (also referred to as pixel density) by employing a unique pixel arrangement such as a PenTile arrangement.

Note that in this specification and the like, the term “island shape” refers to a state where two or more layers formed using the same material in the same process are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as a fine metal mask (an FMM). Accordingly, it is possible to achieve a display apparatus with high definition and a high aperture ratio, which has been difficult to achieve. Moreover, since the EL layers can be formed separately, it is possible to achieve a display apparatus that performs extremely clear display with high contrast and high display quality. Note that fine patterning of the EL layers may be performed using both a metal mask and photolithography, for example.

In addition, part or the whole of an EL layer can be physically divided. This can inhibit leakage current flowing between adjacent light-emitting elements through a layer (also referred to as a common layer) shared by the light-emitting elements. Thus, it is possible to prevent crosstalk due to unintended light emission, so that a display apparatus with extremely high contrast can be achieved. In particular, a display apparatus having high current efficiency at low luminance can be achieved.

Note that in one embodiment of the present invention, the display apparatus can also be obtained by combining a light-emitting element that emits white light with a color filter. In that case, light-emitting elements having the same structure can be employed as light-emitting elements provided in pixels (subpixels) that emit light of different colors, which allows all the layers to be common layers. In addition, part or the whole of each EL layer is separated by photolithography. Thus, leakage current through the common layer is suppressed; accordingly, a high-contrast display apparatus can be achieved. In particular, when an element has a tandem structure in which a plurality of light-emitting layers are stacked with a highly conductive intermediate layer therebetween, leakage current through the intermediate layer can be effectively prevented, so that a display apparatus with high luminance, high definition, and high contrast can be achieved.

Furthermore, an insulating layer covering at least the side surface of the island-shaped light-emitting layer is preferably provided. The insulating layer may cover part of the top surface of an island-shaped EL layer. For the insulating layer, a material having a barrier property against water and oxygen is preferably used. For example, an inorganic insulating film that does not easily allow diffusion of water and oxygen can be used. This can inhibit degradation of the EL layer and can achieve a highly reliable display apparatus.

Moreover, between two adjacent light-emitting elements, there is a region (a concave portion) where none of the EL layers of the light-emitting elements is provided. In the case where a common electrode or a common electrode and a common layer are formed to cover the concave portion, a phenomenon where the common electrode is divided by a step at an end portion of the EL layer (such a phenomenon is also referred to as disconnection) might occur, which might cause insulation of the common electrode over the EL layer. In view of this, a local gap between the two adjacent light-emitting elements is preferably filled with a resin layer (also referred to as local filling planarization, or LFP) functioning as a planarization film. The resin layer has a function of a planarization film. This structure can inhibit disconnection of the common layer or the common electrode and can achieve a highly reliable display apparatus.

More specific structure examples of the display apparatus according to one embodiment of the present invention will be described below with reference to drawings.

### Structure Example

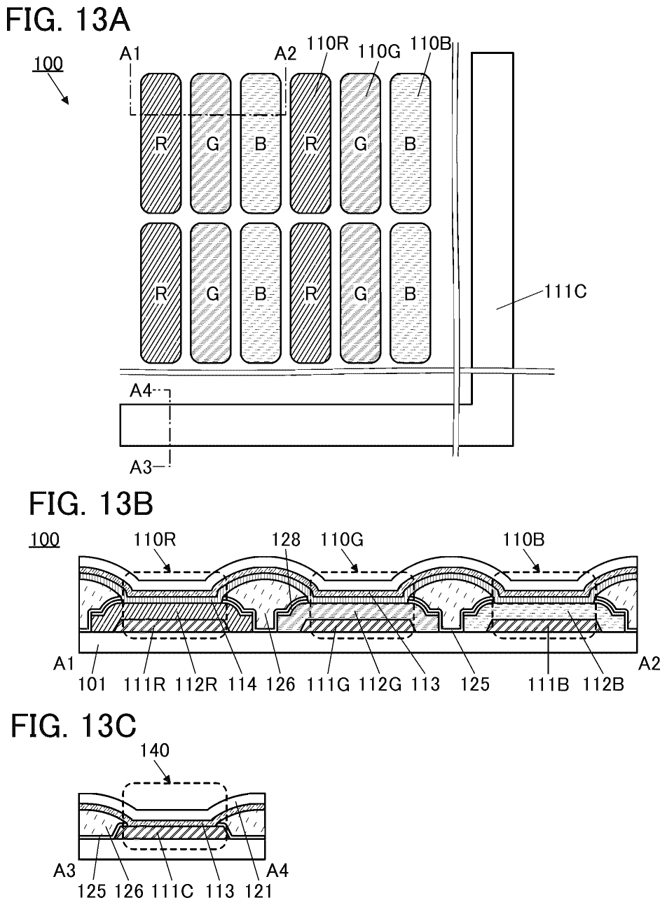

FIG. 13A is a schematic top view of a display apparatus 100 according to one embodiment of the present invention. The display apparatus 100 includes, over a substrate 101, a plurality of light-emitting elements 110R exhibiting red, a plurality of light-emitting elements 110G exhibiting green, and a plurality of light-emitting elements 110B exhibiting blue. In FIG. 13A, light-emitting regions of the light-emitting elements are denoted by R, G, and B to easily distinguish the light-emitting elements.

The light-emitting elements 110R, the light-emitting elements 110G, and the light-emitting elements 110B are each arranged in a matrix. FIG. 13A illustrates what is called a stripe arrangement, in which the light-emitting elements of the same color are arranged in one direction. Note that an arrangement method of the light-emitting elements is not limited thereto; an arrangement method such as an S-stripe arrangement, a delta arrangement, a Bayer arrangement, or a zigzag arrangement may be employed, or a PenTile arrangement, a diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. As examples of a light-emitting substance contained in the EL element, a substance that emits fluorescent light (a fluorescent material), a substance that emits phosphorescent light (a phosphorescent material), and a substance that exhibits thermally activated delayed fluorescence (a thermally activated delayed fluorescent (TADF) material) can be given. As the light-emitting substance contained in the EL element, not only an organic compound but also an inorganic compound (a quantum dot material or the like) can be used.

FIG. 13A also illustrates a connection electrode 111C that is electrically connected to a common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region or two or more sides of the outer periphery of the display region. That is, in the case where the display region has a rectangular top surface shape, the top surface shape of the connection electrode 111C can be a band shape (a rectangle), an L shape, a U shape (a square bracket shape), a tetragonal shape, or the like. Note that in this specification and the like, the top surface shape of a component means the outline of the component in a plan view. A plan view means a view to observe the component from a normal direction of a surface where the component is formed or from a normal direction of a surface of a support (e.g., a substrate) where the component is formed.

FIG. 13B and FIG. 13C are schematic cross-sectional views corresponding to the dashed-dotted line A1-A2 and the dashed-dotted line A3-A4 in FIG. 13A. FIG. 13B is a schematic cross-sectional view of the light-emitting element 110R, the light-emitting element 110G, and the light-emitting element 110B, and FIG. 13C is a schematic cross-sectional view of a connection portion 140 where the connection electrode 111C and the common electrode 113 are connected to each other.

The light-emitting element 110R includes a pixel electrode 111R, an organic layer 112R, a common layer 114, and the common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R includes at least a light-emitting organic compound that emits red light. The organic layer 112G included in the light-emitting element 110G includes at least a light-emitting organic compound that emits green light. The organic layer 112B included in the light-emitting element 110B includes at least a light-emitting organic compound that emits blue light. Each of the organic layer 112R, the organic layer 112G, and the organic layer 112B can also be referred to as an EL layer and includes at least a layer formed using a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 includes a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. In addition, the common electrode 113 and the common layer 114 are each provided as a continuous layer shared by the light-emitting elements. A conductive film having a property of transmitting visible light is used for either the pixel electrodes or the common electrode 113, and a conductive film having a reflective property is used for the other. When the pixel electrodes have a light-transmitting property and the common electrode 113 has a reflective property, a bottom-emission display apparatus can be obtained. In contrast, when the pixel electrodes have a reflective property and the common electrode 113 has a light-transmitting property, a top-emission display apparatus can be obtained. Note that when both the pixel electrodes and the common electrode 113 have a light-transmitting property, a dual-emission display apparatus can also be obtained.

A protective layer 121 is provided over the common electrode 113 to cover the light-emitting element 110R, the light-emitting element 110G, and the light-emitting element 110B.

The protective layer 121 has a function of preventing diffusion of impurities such as water into each light-emitting element from above.

An end portion of the pixel electrode 111 preferably has a tapered shape. In the case where the end portion of the pixel electrode has a tapered shape, the organic layer 112 provided along the side surface of the pixel electrode also has a tapered shape. When the side surface of the pixel electrode has a tapered shape, coverage with the EL layer provided along the side surface of the pixel electrode can be improved. Furthermore, the side surface of the pixel electrode preferably has a tapered shape, in which case foreign matters (also referred to as dust or particles, for example) in the manufacturing process can be easily removed by treatment such as cleaning.

Note that in this specification and the like, a tapered shape indicates a shape in which at least part of the side surface of a structure is inclined to a substrate surface. For example, a tapered shape preferably includes a region where an angle formed between the inclined side surface and the substrate surface (such an angle is also referred to as a taper angle) is less than 90°.

The organic layer 112 has an island shape as a result of processing by a photolithography method. Thus, an angle formed between the top surface and the side surface of an end portion of the organic layer 112 is approximately 90°. By contrast, an organic film formed using an FMM (Fine Metal Mask) or the like has a thickness that tends to gradually decrease with decreasing distance to an end portion, and has a top surface forming a slope in an area extending greater than or equal to 1 mm and less than or equal to 10 mm to the end portion, for example; thus, such an organic film has a shape whose top surface and side surface are difficult to distinguish from each other.

An insulating layer 125, a resin layer 126, and a layer 128 are provided between two adjacent light-emitting elements.

Between two adjacent light-emitting elements, the side surface of the organic layer 112 of one light-emitting element faces the side surface of the organic layer 112 of the other light-emitting element with the resin layer 126 between the side surfaces. The resin layer 126 is located between two adjacent light-emitting elements and is provided so as to fill the region between the end portions of their organic layers 112 and the region between the two organic layers 112. The top surface of the resin layer 126 has a smooth convex shape, and the common layer 114 and the common electrode 113 are provided to cover the top surface of the resin layer 126.

The resin layer 126 functions as a planarization film that fills a step located between two adjacent light-emitting elements. Providing the resin layer 126 can prevent a phenomenon in which the common electrode 113 is divided by a step at the end portion of the organic layer 112 (such a phenomenon is also referred to as disconnection) from occurring and the common electrode over the organic layer 112 from being insulated. The resin layer 126 can also be referred to as an LFP (Local Filling Planarization) layer.

An insulating layer including an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used for the photosensitive resin. As the photosensitive resin, a positive photosensitive material or a negative photosensitive material can be used.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the substrate 101.

The insulating layer 125 is located between the resin layer 126 and the organic layer 112 and functions as a protective film for preventing contact between the resin layer 126 and the organic layer 112. In the case where the organic layer 112 and the resin layer 126 are in contact with each other, the organic layer 112 might be dissolved by an organic solvent or the like used at the time of forming the resin layer 126. Therefore, the insulating layer 125 is provided between the organic layer 112 and the resin layer 126 as described in this embodiment to protect the side surface of the organic layer.

The insulating layer 125 can include an inorganic material. For the insulating layer 125, an inorganic insulating film such as an oxide insulating film, a nitride insulating film, an oxynitride insulating film, or a nitride oxide insulating film can be used, for example. The insulating layer 125 may have either a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, the insulating layer 125 has a small number of pinholes and has an excellent function of protecting the EL layer.

Note that in this specification and the like, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content. For the formation of the insulating layer 125, a sputtering method, a CVD method, a PLD method, an ALD method, or the like can be used. The insulating layer 125 is preferably formed by an ALD method achieving good coverage.

In addition, a structure may be employed in which a reflective film (e.g., a metal film including one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, a material that can be used for the insulating layer 125 can be used. It is particularly preferable to use the same material for the layer 128 and the insulating layer 125 because an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 is provided to cover the common electrode 113.

The protective layer 121 can have, for example, a single-layer structure or a stacked-layer structure that includes at least an inorganic insulating film. Examples of the inorganic insulating film include an oxide film and a nitride film, such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, indium tin oxide, or indium gallium zinc oxide may be used for the protective layer 121.

For the protective layer 121, a stacked film of an inorganic insulating film and an organic insulating film can be used. For example, a structure in which an organic insulating film is held between a pair of inorganic insulating films is preferable. Furthermore, the organic insulating film preferably functions as a planarization film. This enables the top surface of the organic insulating film to be flat, which results in improved coverage with the inorganic insulating film thereover and a higher barrier property. Moreover, the top surface of the protective layer 121 is flat; therefore, when a structure (e.g., a color filter, an electrode of a touch sensor, a lens array, or the like) is provided above the protective layer 121, the structure can be less affected by an uneven shape caused by a lower structure.

FIG. 13C illustrates the connection portion 140 in which the connection electrode 111C and the common electrode 113 are electrically connected to each other. In the connection portion 140, an opening portion is provided in the insulating layer 125 and the resin layer 126 over the connection electrode 111C. The connection electrode 111C and the common electrode 113 are electrically connected to each other in the opening portion.

Note that although FIG. 13C illustrates the connection portion 140 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, the common layer 114 can be formed to be thin using a material with sufficiently low electrical resistivity; thus, problems do not arise in many cases even when the common layer 114 is located in the connection portion 140. Accordingly, the common electrode 113 and the common layer 114 can be formed using the same shielding mask, so that manufacturing cost can be reduced.

The above is the description of the structure example of the display apparatus.

### [Pixel Layout]

Pixel layout different from that in FIG. 13A will be mainly described below. There is no particular limitation on the arrangement of light-emitting elements (subpixels), and any of a variety of methods can be employed.

In addition, examples of the top surface shape of the subpixel include polygons such as a triangle, a tetragon (including a rectangle and a square), and a pentagon; these polygons with rounded corners; an ellipse; and a circle. Here, the top surface shape of the subpixel corresponds to the top surface shape of a light-emitting region of the light-emitting element.

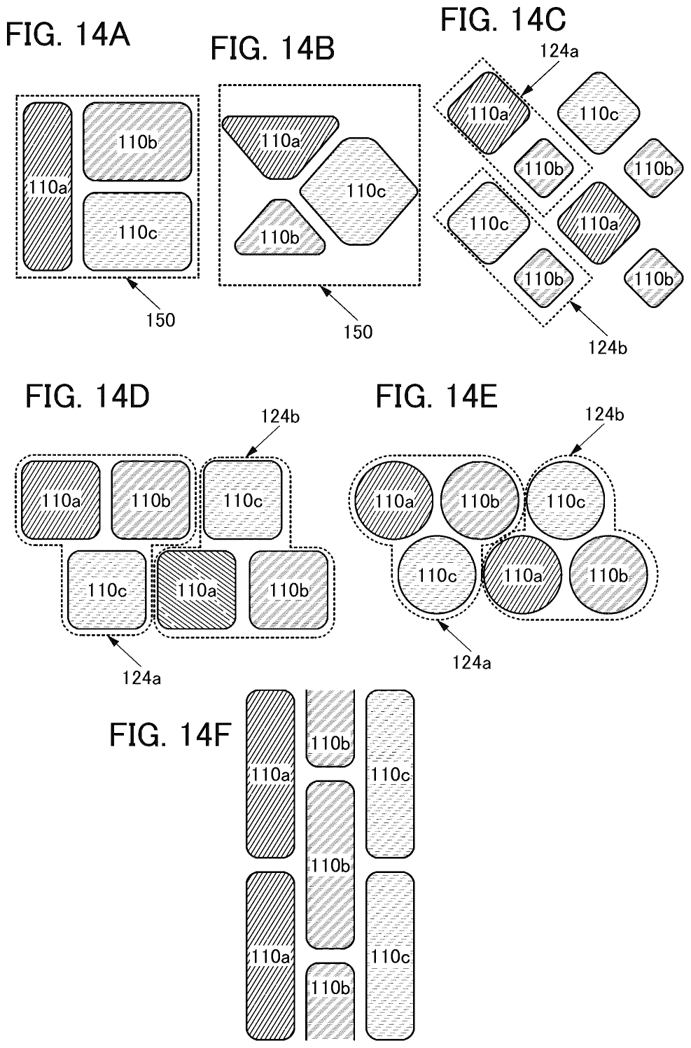

A pixel 150 illustrated in FIG. 14A employs an S-stripe arrangement. The pixel 150 illustrated in FIG. 14A is composed of three subpixels: light-emitting elements 110a, 110b, and 110c. For example, the light-emitting element 110a may be a blue-light-emitting element, the light-emitting element 110b may be a red-light-emitting element, and the light-emitting element 110c may be a green-light-emitting element.

The pixel 150 illustrated in FIG. 14B includes the light-emitting element 110a having a substantially trapezoidal top surface shape with rounded corners, the light-emitting element 110b having a substantially triangle top surface shape with rounded corners, and the light-emitting element 110c having a substantially tetragonal or substantially hexagonal top surface shape with rounded corners. In addition, the light-emitting element 110a has a larger light-emitting area than the light-emitting element 110b. In this manner, the shapes and sizes of the light-emitting elements can be determined independently. For example, the size of a light-emitting element with higher reliability can be made smaller. For example, the light-emitting element 110a may be a green-light-emitting element, the light-emitting element 110b may be a red-light-emitting element, and the light-emitting element 110c may be a blue-light-emitting element.

Pixels 124a and 124b illustrated in FIG. 14C employ a PenTile arrangement. FIG. 14C illustrates an example in which the pixels 124a each including the light-emitting element 110a and the light-emitting element 110b and the pixels 124b each including the light-emitting element 110b and the light-emitting element 110c are alternately arranged. For example, the light-emitting element 110a may be a red-light-emitting element, the light-emitting element 110b may be a green-light-emitting element, and the light-emitting element 110c may be a blue-light-emitting element.

The pixels 124a and 124b illustrated in FIG. 14D and FIG. 14E employ a delta arrangement. The pixel 124a includes two light-emitting elements (the light-emitting elements 110a and 110b) in an upper row (a first row) and one light-emitting element (the light-emitting element 110c) in a lower row (a second row). The pixel 124b includes one light-emitting element (the light-emitting element 110c) in the upper row (the first row) and two light-emitting elements (the light-emitting elements 110a and 110b) in the lower row (the second row). For example, the light-emitting element 110a may be a red-light-emitting element, the light-emitting element 110b may be a green-light-emitting element, and the light-emitting element 110c may be a blue-light-emitting element.

FIG. 14D illustrates an example in which each light-emitting element has a substantially tetragonal top surface shape with rounded corners, and FIG. 14E illustrates an example in which each light-emitting element has a circular top surface shape.

FIG. 14F illustrates an example in which light-emitting elements of different colors are arranged in a zigzag manner. Specifically, the positions of top sides of two light-emitting elements arranged in a column direction (e.g., the light-emitting element 110a and the light-emitting element 110b or the light-emitting element 110b and the light-emitting element 110c) are not aligned in a top view. For example, the light-emitting element 110a may be a red-light-emitting element, the light-emitting element 110b may be a green-light-emitting element, and the light-emitting element 110c may be a blue-light-emitting element.

In a photolithography method, as a pattern to be formed by processing becomes finer, the influence of light diffraction becomes more difficult to ignore; accordingly, fidelity in transferring a photomask pattern by light exposure is degraded, and it becomes difficult to process a resist mask into a desired shape. Thus, a pattern with rounded corners is likely to be formed even with a rectangular photomask pattern. Consequently, a light-emitting element sometimes has a polygonal top surface shape with rounded corners, an elliptical top surface shape, a circular top surface shape, or the like.

Furthermore, in a method for manufacturing a display panel according to one embodiment of the present invention, the EL layer is processed into an island shape with the use of a resist mask. A resist film formed over the EL layer needs to be cured at a temperature lower than the upper temperature limit of the EL layer. Thus, the resist film is insufficiently cured in some cases depending on the upper temperature limit of the material of the EL layer and the curing temperature of the resist material. An insufficiently cured resist film might have a shape different from a desired shape at the time of processing. As a result, the EL layer sometimes has a polygonal top surface shape with rounded corners, an elliptical top surface shape, a circular top surface shape, or the like. For example, when a resist mask with a square top surface shape is intended to be formed, a resist mask with a circular top surface shape might be formed, and the EL layer might have a circular top surface.

Note that to obtain a desired top surface shape of the EL layer, a technique of correcting a mask pattern in advance so that a transferred pattern agrees with a design pattern (an OPC (Optical Proximity Correction) technique) may be used. Specifically, with the OPC technique, a pattern for correction is added to a corner portion or the like of a figure on a mask pattern.

The above is the description of the pixel layout.

At least part of this embodiment can be implemented in combination with the other embodiments described in this specification as appropriate.

### Embodiment 4

In this embodiment, structure examples of a display apparatus that can be employed for the image processing system of one embodiment of the present invention will be described.

The display apparatus of this embodiment can be used for, for example, display portions of a digital camera, a digital video camera, a digital photo frame, a mobile phone, a portable game machine, a smartphone, a wristwatch-type terminal, a tablet terminal, a portable information terminal, an audio reproducing device, a goggles-type display, and the like in addition to electronic devices with comparatively large screens, such as a television device, a desktop or notebook personal computer, a monitor for a computer or the like, digital signage, and a large game machine like a pachinko machine.

### [Display Apparatus 400]

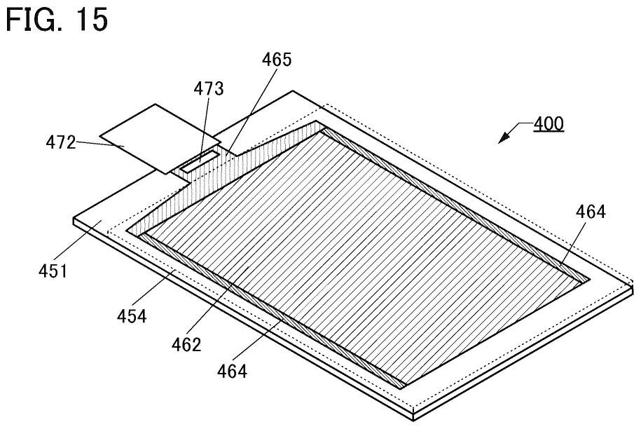

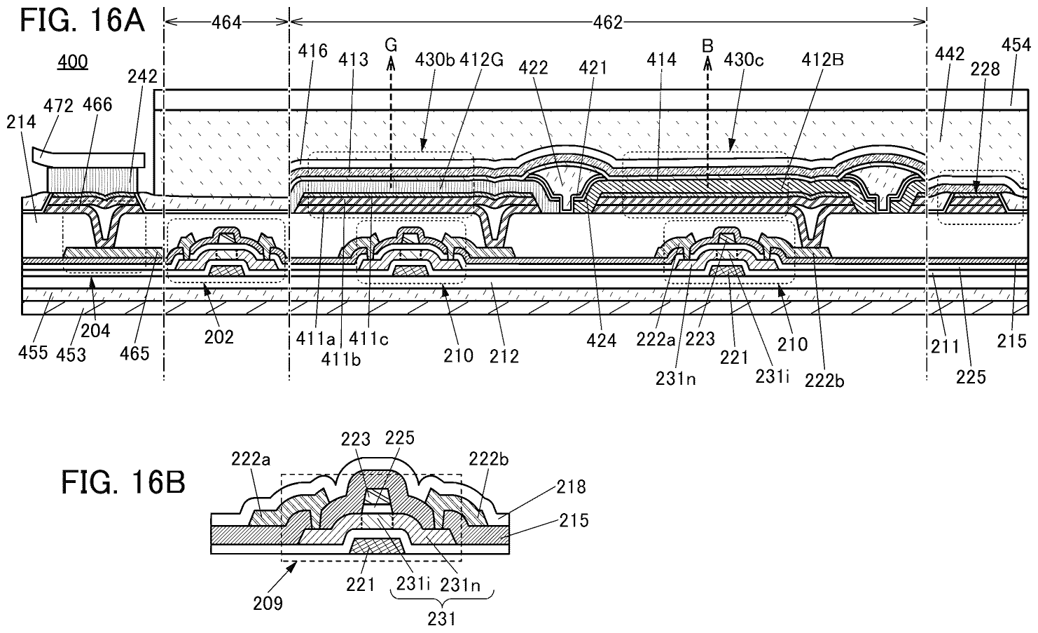

FIG. 15 is a perspective view of a display apparatus 400, and FIG. 16A is a cross-sectional view of the display apparatus 400.

The display apparatus 400 has a structure in which a substrate 454 and a substrate 451 are attached to each other. In FIG. 15, the substrate 454 is denoted by a dashed line.

The display apparatus 400 includes a display portion 462, a circuit 464, a wiring 465, and the like. FIG. 15 illustrates an example in which an IC 473 and an FPC 472 are implemented on the display apparatus 400. Thus, the structure illustrated in FIG. 15 can be regarded as a display module that includes the display apparatus 400, the IC (integrated circuit), and the FPC.

As the circuit 464, a scan line driver circuit can be used, for example.

The wiring 465 has a function of supplying a signal and power to the display portion 462 and the circuit 464. The signal and power are input to the wiring 465 from the outside through the FPC 472 or input to the wiring 465 from the IC 473.

FIG. 15 illustrates an example in which the IC 473 is provided over the substrate 451 by a COG (Chip On Glass) method, a COF (Chip on Film) method, or the like. An IC that includes a scan line driver circuit, a signal line driver circuit, or the like can be employed as the IC 473, for example. Note that the display apparatus 400 and the display module are not necessarily provided with an IC. In addition, the IC may be implemented on the FPC by a COF method or the like.

FIG. 16A illustrates examples of cross sections of part of a region that includes the FPC 472, part of the circuit 464, part of the display portion 462, and part of a region that includes a connection portion in the display apparatus 400. FIG. 16A specifically illustrates an example of a cross section of a region provided with a light-emitting element 430b, which emits green light, and a light-emitting element 430c, which emits blue light, in the display portion 462.

The display apparatus 400 illustrated in FIG. 16A includes a transistor 202, transistors 210, the light-emitting element 430b, the light-emitting element 430c, and the like between a substrate 453 and the substrate 454.

Here, in the case where a pixel of the display apparatus includes three kinds of subpixels that include light-emitting elements emitting light of different colors, subpixels of three colors of red (R), green (G), and blue (B), subpixels of three colors of yellow (Y), cyan (C), and magenta (M), and the like can be given as examples of the three subpixels. In the case where the pixel includes four subpixels, subpixels of four colors of R, G, B, and white (W), subpixels of four colors of R, G, B, and Y, and the like can be given as examples of the four subpixels.

The substrate 454 and a protective layer 416 are bonded to each other with an adhesive layer 442. The adhesive layer 442 is provided to overlap with the light-emitting element 430b and the light-emitting element 430c, and the display apparatus 400 employs a solid sealing structure.

The light-emitting element 430b and the light-emitting element 430c each include a conductive layer 411a, a conductive layer 411b, and a conductive layer 411c as a pixel electrode. The conductive layer 411b has a property of reflecting visible light and functions as a reflective electrode. The conductive layer 411c has a property of transmitting visible light and functions as an optical adjustment layer.

The conductive layer 411a is connected to a conductive layer 222b included in the transistor 210 through an opening provided in an insulating layer 214. The transistor 210 has a function of controlling driving of the light-emitting element.

An EL layer 412G or an EL layer 412B is provided to cover the pixel electrode. An insulating layer 421 is provided in contact with the side surface of the EL layer 412G and the side surface of the EL layer 412B, and a resin layer 422 is provided to fill a concave portion of the insulating layer 421. A layer 424 is provided between the EL layer 412G and the insulating layer 421 and between the EL layer 412B and the insulating layer 421. A common layer 414, a common electrode 413, and the protective layer 416 are provided to cover the EL layer 412G and the EL layer 412B.

Light emitted from the light-emitting element is emitted toward the substrate 454 side. For the substrate 454, a material having a high property of transmitting visible light is preferably used.

The transistor 202 and the transistor 210 are each formed over the substrate 451. These transistors can be manufactured using the same material in the same process.

The substrate 453 and an insulating layer 212 are attached to each other with an adhesive layer 455.

In a method for manufacturing the display apparatus 400, first, a manufacture substrate provided with the insulating layer 212, the transistors, the light-emitting elements, and the like is attached to the substrate 454 with the adhesive layer 442. Then, the substrate 453 is attached to a surface exposed by separation of the manufacture substrate, so that the components formed over the manufacture substrate are transferred to the substrate 453. The substrate 453 and the substrate 454 each preferably have flexibility. This can increase the flexibility of the display apparatus 400.

An inorganic insulating film that can be used for each of an insulating layer 211 and an insulating layer 215 can be used for the insulating layer 212.

A connection portion 204 is provided in a region of the substrate 453 where the substrate 453 and the substrate 454 do not overlap with each other. In the connection portion 204, the wiring 465 is electrically connected to the FPC 472 through a conductive layer 466 and a connection layer 242. The conductive layer 466 can be obtained by processing the same conductive film as the pixel electrode. Thus, the connection portion 204 and the FPC 472 can be electrically connected to each other through the connection layer 242.

Each of the transistor 202 and the transistor 210 includes a conductive layer 221 functioning as a gate, the insulating layer 211 functioning as a gate insulating layer, a semiconductor layer 231 including a channel formation region 231i and a pair of low-resistance regions 231n, a conductive layer 222a connected to one of the pair of low-resistance regions 231n, the conductive layer 222b connected to the other of the pair of low-resistance regions 231n, an insulating layer 225 functioning as a gate insulating layer, a conductive layer 223 functioning as a gate, and the insulating layer 215 covering the conductive layer 223. The insulating layer 211 is located between the conductive layer 221 and the channel formation region 231i. The insulating layer 225 is located between the conductive layer 223 and the channel formation region 231i.

The conductive layer 222a and the conductive layer 222b are connected to the low-resistance regions 23 In through openings provided in the insulating layer 215. One of the conductive layer 222a and the conductive layer 222b functions as a source, and the other of the conductive layer 222a and the conductive layer 222b functions as a drain.

FIG. 16A illustrates an example in which the insulating layer 225 covers the top surface and side surfaces of the semiconductor layer. The conductive layer 222a and the conductive layer 222b are connected to the low-resistance regions 23 In through openings provided in the insulating layer 225 and the insulating layer 215.

By contrast, in a transistor 209 illustrated in FIG. 16B, the insulating layer 225 overlaps with the channel formation region 231i of the semiconductor layer 231 and does not overlap with the low-resistance regions 231n. The structure illustrated in FIG. 16B can be manufactured by processing the insulating layer 225 with the conductive layer 223 as a mask, for example. In FIG. 16B, the insulating layer 215 is provided to cover the insulating layer 225 and the conductive layer 223, and the conductive layer 222a and the conductive layer 222b are connected to the low-resistance regions 231n through openings in the insulating layer 215. Furthermore, an insulating layer 218 covering the transistor may be provided.

There is no particular limitation on the structure of the transistors included in the display apparatus of this embodiment. For example, a planar transistor, a staggered transistor, an inverted staggered transistor, or the like can be used. In addition, either a top-gate transistor structure or a bottom-gate transistor structure may be employed. Alternatively, gates may be provided above and below a semiconductor layer where a channel is formed.

The transistor 202 and the transistor 210 each have the structure in which the semiconductor layer where a channel is formed is held between two gates. The two gates may be connected to each other and supplied with the same signal to drive the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the semiconductor layer of the transistor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used to inhibit degradation of transistor characteristics.

The semiconductor layer of the transistor preferably includes a metal oxide (also referred to as an oxide semiconductor). That is, a transistor that includes a metal oxide in its channel formation region (hereinafter an OS transistor) is preferably used in the display apparatus of this embodiment.

The band gap of a metal oxide used for the semiconductor layer of the transistor is preferably greater than or equal to 2 eV, further preferably greater than or equal to 2.5 eV. With the use of a metal oxide having a wide band gap, the off-state current of the OS transistor can be reduced.

The metal oxide preferably contains at least indium or zinc, and further preferably contains indium and zinc. The metal oxide preferably contains indium, M (M is one or more selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example.

Alternatively, the semiconductor layer of the transistor may include silicon. Examples of silicon include amorphous silicon and crystalline silicon (low-temperature polysilicon, single crystal silicon, or the like).

The transistor included in the circuit 464 and the transistor included in the display portion 462 may have either the same structure or different structures. A plurality of transistors included in the circuit 464 may have either the same structure or two or more kinds of structures. Similarly, a plurality of transistors included in the display portion 462 may have either the same structure or two or more kinds of structures.

A material that does not easily allow diffusion of impurities such as water and hydrogen is preferably used for at least one of the insulating layers covering the transistors. In that case, such an insulating layer can function as a barrier layer. Such a structure can effectively inhibit diffusion of impurities into the transistors from the outside and can increase the reliability of the display apparatus.

An inorganic insulating film is preferably used for each of the insulating layer 211, the insulating layer 212, the insulating layer 215, the insulating layer 218, and the insulating layer 225. As the inorganic insulating film, a silicon nitride film, a silicon oxynitride film, a silicon oxide film, a silicon nitride oxide film, an aluminum oxide film, an aluminum nitride film, or the like can be used, for example. Alternatively, a hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack that includes two or more of the above inorganic insulating films may also be used.

An organic insulating film is suitable for the insulating layer 214 functioning as a planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins.

A variety of optical members can be arranged along the inner or outer surface of the substrate 454. Examples of the optical members include a light-blocking layer, a polarizing plate, a retardation plate, a light diffusion layer (a diffusion film or the like), an anti-reflection layer, a microlens array, and a light-condensing film. Furthermore, an antistatic film inhibiting attachment of dust, a water repellent film suppressing attachment of stain, a hard coat film inhibiting generation of a scratch caused by the use, a shock absorbing layer, or the like may be provided on the outside of the substrate 454.

Providing the protective layer 416 that covers the light-emitting elements can inhibit entry of impurities such as water into the light-emitting elements, so that the reliability of the light-emitting elements can be increased.

FIG. 16A illustrates a connection portion 228. In the connection portion 228, the common electrode 413 is electrically connected to a wiring. FIG. 16A illustrates an example in which the wiring has the same stacked-layer structure as the pixel electrode.

For each of the substrate 453 and the substrate 454, glass, quartz, ceramics, sapphire, a resin, a metal, an alloy, a semiconductor, or the like can be used. For the substrate on the side from which light from the light-emitting elements is extracted, a material that transmits the light is used. When a flexible material is used for the substrate 453 and the substrate 454, the flexibility of the display apparatus can be increased. Furthermore, a polarizing plate may be used as the substrate 453 or the substrate 454.

For each of the substrate 453 and the substrate 454, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (nylon, aramid, or the like), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, cellulose nanofiber, or the like can be used. Glass that is thin enough to have flexibility may be used for one or both of the substrate 453 and the substrate 454.

For the adhesive layer, any of a variety of curable adhesives, e.g., a photocurable adhesive such as an ultraviolet curable adhesive, a reactive curable adhesive, a thermosetting adhesive, and an anaerobic adhesive, can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. Alternatively, a two-liquid-mixture-type resin may be used. Alternatively, an adhesive sheet or the like may be used.

For the connection layer 242, an anisotropic conductive film (ACF), an anisotropic conductive paste (ACP), or the like can be used.

As examples of materials that can be used for conductive layers such as a variety of wirings and electrodes included in the display apparatus, in addition to a gate, a source, and a drain of a transistor, a metal such as aluminum, titanium, chromium, nickel, copper, yttrium, zirconium, molybdenum, silver, tantalum, or tungsten, an alloy containing the metal as its main component, and the like can be given. A film including any of these materials can be used as a single layer or in a stacked-layer structure.

In addition, as a light-transmitting conductive material, a conductive oxide such as indium oxide, indium tin oxide, indium zinc oxide, zinc oxide, or zinc oxide containing gallium, or graphene can be used. Alternatively, a metal material such as gold, silver, platinum, magnesium, nickel, tungsten, chromium, molybdenum, iron, cobalt, copper, palladium, or titanium, or an alloy material containing the metal material can be used. Alternatively, a nitride of the metal material (e.g., titanium nitride) or the like may be used. Note that in the case of using the metal material or the alloy material (or the nitride thereof), the material is preferably made thin enough to have a light-transmitting property. Furthermore, a stacked-layer film of the above materials can be used for the conductive layer. For example, a stacked-layer film of indium tin oxide and an alloy of silver and magnesium, or the like is preferably used to achieve higher conductivity. They can also be used for the conductive layers such as a variety of wirings and electrodes included in the display apparatus, and the conductive layer (the conductive layer functioning as the pixel electrode or the common electrode) included in the light-emitting element.

As examples of an insulating material that can be used for each insulating layer, a resin such as an acrylic resin or an epoxy resin, and an inorganic insulating material such as silicon oxide, silicon oxynitride, silicon nitride oxide, silicon nitride, or aluminum oxide can be given.

### [Display Apparatus 400A]

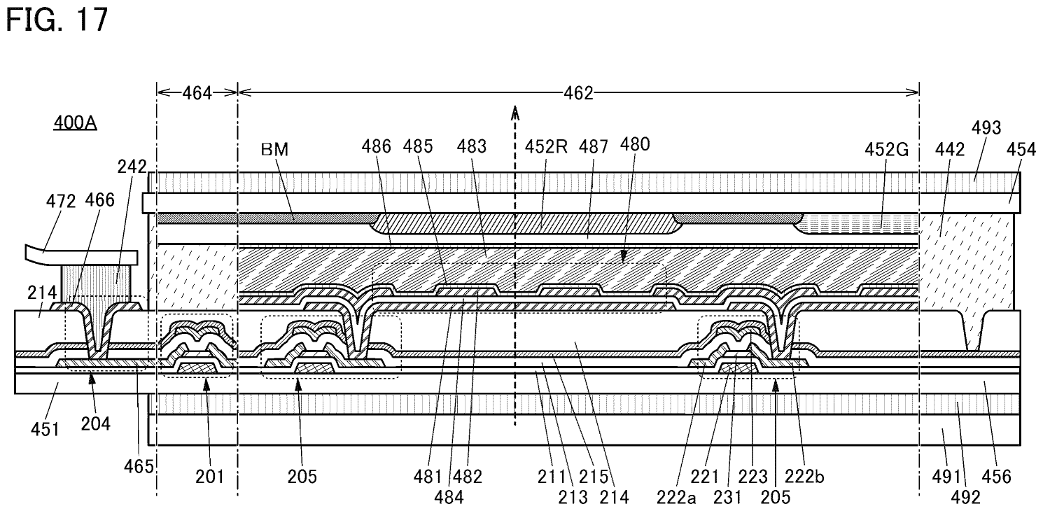

A display apparatus 400A illustrated in FIG. 17 is an example of a liquid crystal display apparatus that includes a liquid crystal element as a display element.

The display apparatus 400A includes a transistor 201, transistors 205, a liquid crystal element 480, and the like between a substrate 456 and the substrate 454.

In FIG. 17, bottom-gate transistors are shown as the transistor 201 and the transistors 205. The transistor 201 and the transistors 205 each include the conductive layer 221 functioning as a gate electrode, the insulating layer 211 functioning as a gate insulating layer, the semiconductor layer 231, the conductive layer 222a and the conductive layer 222b functioning as a source electrode and a drain electrode, the conductive layer 223 functioning as a second gate electrode, and an insulating layer 213 functioning as a second gate insulating layer. The transistors are covered with the insulating layer 215.

Each of the transistor 201 and the transistors 205 preferably includes a metal oxide in the semiconductor layer 231.

The liquid crystal element 480 illustrated in FIG. 17 is a liquid crystal element in a transverse electric field mode. The liquid crystal element 480 includes a pixel electrode 481, a common electrode 482, and a liquid crystal layer 483. The common electrode 482 is provided over the pixel electrode with an insulating layer 484 therebetween. The liquid crystal layer 483 is provided over the pixel electrode 481 and the common electrode 482.

A color filter 452R, a color filter 452G, and a light-blocking layer BM are provided on the substrate 456 side of the substrate 454, and an overcoat 487 is provided to cover them. The color filter 452R and the color filter 452G transmit light of different colors.

An alignment film 485 and an alignment film 486 are provided in contact with the liquid crystal layer 483. The alignment film 485 is provided to cover the insulating layer 484 and the common electrode 482. The alignment film 486 is provided to cover the overcoat 487.

A backlight unit 491 is provided outside the substrate 456, and a polarizing plate 492 is provided between the substrate 456 and the backlight unit 491. Furthermore, a polarizing plate 493 is provided outside the substrate 454.

Light from the backlight unit 491 is emitted to the outside of the display apparatus through the polarizing plate 492, the substrate 456, the pixel electrode 481, the common electrode 482, the liquid crystal layer 483, the color filter 452R, the polarizing plate 493, and the substrate 454. In accordance with the potential difference between the pixel electrode 481 and the common electrode 482, the alignment of liquid crystals is controlled and the amount of transmitted light is changed. As materials of these layers that transmit light from the backlight unit 491, visible-light-transmitting materials are used.

For the liquid crystal layer 483, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. In the case where a horizontal electric field mode is employed, a liquid crystal exhibiting a blue phase for which an alignment film is not used may be used.

As the mode of the liquid crystal element, a TN (Twisted Nematic) mode, a VA (Vertical Alignment) mode, an IPS (In-Plane-Switching) mode, an FFS (Fringe Field Switching) mode, an ASM (Axially Symmetric aligned Micro-cell) mode, an OCB (Optically Compensated Birefringence) mode, an ECB (Electrically Controlled Birefringence) mode, a guest-host mode, or the like can be employed.

A scattering liquid crystal employing a polymer dispersed liquid crystal, a polymer network liquid crystal, or the like can be used for the liquid crystal layer 483. In that case, monochrome display may be performed without providing the color filter 452R or the like, or color display may be performed using the color filter 452R and the like.

As a method for driving the liquid crystal element, a time-division display method (also referred to as a field-sequential driving method) by which color display is performed by a successive additive color mixing method may be used. In that case, a structure in which the color filter 452R and the like are not provided can be employed. Using the time-division display method eliminates the need for providing subpixels that exhibit R (red), G (green), and B (blue), for example, bringing advantages such as an increase in the aperture ratio of pixels and an increase in definition.

At least part of this embodiment can be implemented in combination with the other embodiments described in this specification as appropriate.

### Embodiment 5

In this embodiment, a light-emitting element (also referred to as a light-emitting device) that can be used in the display apparatus of the image processing system of one embodiment of the present invention will be described.

In this specification and the like, a device fabricated using a metal mask or an FMM (a fine metal mask or a high-definition metal mask) may be referred to as a device having an MM (metal mask) structure. In this specification and the like, a device fabricated without using a metal mask or an FMM may be referred to as a device having an MML (metal maskless) structure.

In this specification and the like, a structure where light-emitting layers in light-emitting devices of different colors (here, blue (B), green (G), and red (R)) are separately formed or separately patterned is sometimes referred to as an SBS (Side By Side) structure. In this specification and the like, a light-emitting device capable of emitting white light may be referred to as a white-light-emitting device. Note that a combination of white-light-emitting devices with coloring layers (e.g., color filters) enables a full-color display apparatus light-emitting device.

### [Light-Emitting Device]

Structures of light-emitting devices can be classified roughly into a single structure and a tandem structure. A device with a single structure includes one light-emitting unit between a pair of electrodes. The light-emitting unit includes one or more light-emitting layers. To obtain white light emission with a single structure, two or more light-emitting layers are selected such that a white color can be produced by light emission of the light-emitting layers. For example, when the emission color of a first light-emitting layer and the emission color of a second light-emitting layer are complementary colors, a light-emitting device can emit white light as a whole. To obtain white light emission by using three or more light-emitting layers, the light-emitting device is configured to emit white light as a whole by combining the emission colors of the three or more light-emitting layers.

A light-emitting device with a tandem structure includes a plurality of light-emitting units between a pair of electrodes. Each light-emitting unit includes one or more light-emitting layers. When light-emitting layers that emit light of the same color are used in each light-emitting unit, luminance per predetermined current can be increased, and the light-emitting device can have higher reliability than that with a single structure. To obtain white light emission in a tandem structure, the structure is employed in which white light emission can be obtained by combining light from light-emitting layers of a plurality of light-emitting units. Note that a combination of emission colors for obtaining white light emission is similar to that in the case of a single structure. In a device with a tandem structure, an intermediate layer such as a charge-generation layer is suitably provided between a plurality of light-emitting units.

When a white-light-emitting device and a light-emitting device with an SBS structure are compared with each other, the light-emitting device with the SBS structure can have lower power consumption than the white-light-emitting device. Meanwhile, the white-light-emitting device can achieve lower manufacturing cost and a higher manufacturing yield because the manufacturing process of the white-light-emitting device is simpler than that of the light-emitting device with the SBS structure.

### Structure Example of Light-Emitting Device

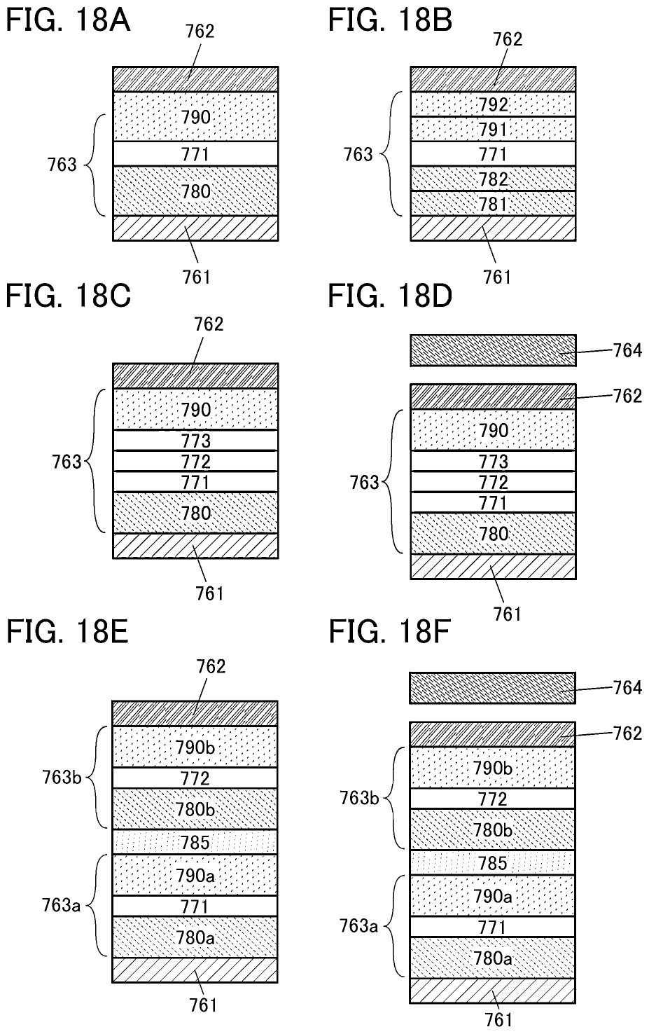

As illustrated in FIG. 18A, the light-emitting device includes an EL layer 763 between a pair of electrodes (a lower electrode 761 and an upper electrode 762). The EL layer 763 can be composed of a plurality of layers such as a layer 780, a light-emitting layer 771, and a layer 790.

The light-emitting layer 771 includes at least a light-emitting substance (also referred to as a light-emitting material).

In the case where the lower electrode 761 is an anode and the upper electrode 762 is a cathode, the layer 780 includes one or more of a layer formed using a substance with a high hole-injection property (a hole-injection layer), a layer formed using a substance with a high hole-transport property (a hole-transport layer), and a layer formed using a substance with a high electron-blocking property (an electron-blocking layer). Furthermore, the layer 790 includes one or more of a layer formed using a substance with a high electron-injection property (an electron-injection layer), a layer formed using a substance with a high electron-transport property (an electron-transport layer), and a layer formed using a substance with a high hole-blocking property (a hole-blocking layer). In the case where the lower electrode 761 is a cathode and the upper electrode 762 is an anode, the above structures of the layer 780 and the layer 790 are replaced with each other.

The structure that includes the layer 780, the light-emitting layer 771, and the layer 790 provided between the pair of electrodes can function as a single light-emitting unit, and the structure in FIG. 18A is referred to as a single structure in this specification.

FIG. 18B illustrates a variation example of the EL layer 763 included in the light-emitting device illustrated in FIG. 18A. Specifically, the light-emitting device illustrated in FIG. 18B includes a layer 781 over the lower electrode 761, a layer 782 over the layer 781, the light-emitting layer 771 over the layer 782, a layer 791 over the light-emitting layer 771, a layer 792 over the layer 791, and the upper electrode 762 over the layer 792.

In the case where the lower electrode 761 is an anode and the upper electrode 762 is a cathode, the layer 781 can be a hole-injection layer, the layer 782 can be a hole-transport layer, the layer 791 can be an electron-transport layer, and the layer 792 can be an electron-injection layer, for example. In the case where the lower electrode 761 is a cathode and the upper electrode 762 is an anode, the layer 781 can be an electron-injection layer, the layer 782 can be an electron-transport layer, the layer 791 can be a hole-transport layer, and the layer 792 can be a hole-injection layer. With such a layered structure, carriers can be efficiently injected to the light-emitting layer 771, and the efficiency of the recombination of carriers in the light-emitting layer 771 can be enhanced.

Note that structures in which a plurality of light-emitting layers (the light-emitting layers 771, 772, and 773) are provided between the layer 780 and the layer 790 as illustrated in FIG. 18C and FIG. 18D are other variations of the single structure. Although FIG. 18C and FIG. 18D illustrate the examples where three light-emitting layers are included, the light-emitting layer in the light-emitting device with a single structure may include two or four or more light-emitting layers. In addition, the light-emitting device with a single structure may include a buffer layer between two light-emitting layers.

A structure where a plurality of light-emitting units (a light-emitting unit 763a and a light-emitting unit 763b) are connected in series with a charge-generation layer 785 (also referred to as an intermediate layer) therebetween as illustrated in FIG. 18E and FIG. 18F is referred to as a tandem structure in this specification. Note that a tandem structure may be referred to as a stack structure. A tandem structure enables a light-emitting device capable of high-luminance light emission. In obtaining the same luminance, a tandem structure needs a lower current than a single structure, leading to higher reliability.

Note that FIG. 18D and FIG. 18F illustrate examples where the display apparatus includes a layer 764 overlapping with the light-emitting device. FIG. 18D illustrates an example where the layer 764 overlaps with the light-emitting device illustrated in FIG. 18C, and FIG. 18F illustrates an example where the layer 764 overlaps with the light-emitting device illustrated in FIG. 18E. In FIG. 18D and FIG. 18F, a conductive film transmitting visible light is used for the upper electrode 762 to extract light to the upper electrode 762 side.

One or both of a color conversion layer and a color filter (a coloring layer) can be used as the layer 764.

In FIG. 18C and FIG. 18D, light-emitting substances that emit light of the same color, or moreover, the same light-emitting substance may be used for the light-emitting layer 771, the light-emitting layer 772, and the light-emitting layer 773. For example, a light-emitting substance that emits blue light may be used for the light-emitting layer 771, the light-emitting layer 772, and the light-emitting layer 773. In a subpixel that emits blue light, blue light emitted from the light-emitting device can be extracted. In a subpixel that emits red light and a subpixel that emits green light, by providing a color conversion layer as the layer 764 illustrated in FIG. 18D, blue light emitted from the light-emitting device can be converted into light with a longer wavelength, and red light or green light can be extracted. As the layer 764, both a color conversion layer and a coloring layer are preferably used. In some cases, part of light emitted from the light-emitting device is transmitted through the color conversion layer without being converted. When light transmitted through the color conversion layer is extracted through the coloring layer, light other than light of the intended color can be absorbed by the coloring layer, and the color purity of light exhibited by a subpixel can be improved.

In FIG. 18C and FIG. 18D, light-emitting substances that emit light of different colors may be used for the light-emitting layer 771, the light-emitting layer 772, and the light-emitting layer 773. White light emission can be obtained when light emitted by the light-emitting layer 771, light emitted by the light-emitting layer 772, and light emitted by the light-emitting layer 773 are appropriately combined. The light-emitting device with a single structure preferably includes a light-emitting layer formed using a light-emitting substance emitting blue light and a light-emitting layer formed using a light-emitting substance emitting visible light with a wavelength longer than that of blue light, for example.

A color filter may be provided as the layer 764 illustrated in FIG. 18D. When white light passes through the color filter, light of a desired color can be obtained.

In the case where the light-emitting device with a single structure includes three light-emitting layers, for example, the light-emitting device preferably includes a light-emitting layer formed using a light-emitting substance emitting red (R) light, a light-emitting layer formed using a light-emitting substance emitting green (G) light, and a light-emitting layer formed using a light-emitting substance emitting blue (B) light. The stacking order of the light-emitting layers can be RGB from an anode side or RBG from an anode side, for example. In that case, a buffer layer may be provided between R and G or between R and B.

For example, in the case where the light-emitting device with a single structure includes two light-emitting layers, the light-emitting device preferably includes a light-emitting layer formed using a light-emitting substance emitting blue (B) light and a light-emitting layer formed using a light-emitting substance emitting yellow (Y) light. Such a structure may be referred to as a light-emitting device having a BY single structure.

Also in FIG. 18C and FIG. 18D, the layer 780 and the layer 790 may each independently have a stacked-layer structure of two or more layers as illustrated in FIG. 18B.

In FIG. 18E and FIG. 18F, light-emitting substances that emit light of the same color, or moreover, the same light-emitting substance may be used for the light-emitting layer 771 and the light-emitting layer 772. For example, in light-emitting devices included in subpixels emitting light of different colors, a light-emitting substance that emits blue light may be used for each of the light-emitting layer 771 and the light-emitting layer 772. In a subpixel that emits blue light, blue light emitted from the light-emitting device can be extracted. In a subpixel that emits red light and a subpixel that emits green light, by providing a color conversion layer as the layer 764 illustrated in FIG. 18F, blue light emitted from the light-emitting device can be converted into light with a longer wavelength, and red light or green light can be extracted. As the layer 764, both a color conversion layer and a coloring layer are preferably used.

In the case where light-emitting devices with the structure illustrated in FIG. 18E or FIG. 18F are used in subpixels emitting light of different colors, light-emitting substances may be different between the subpixels. Specifically, in the light-emitting device included in the subpixel emitting red light, a light-emitting substance that emits red light may be used for each of the light-emitting layer 771 and the light-emitting layer 772. Similarly, in the light-emitting device included in the subpixel emitting green light, a light-emitting substance that emits green light may be used for each of the light-emitting layer 771 and the light-emitting layer 772. In the light-emitting device included in the subpixel emitting blue light, a light-emitting substance that emits blue light may be used for each of the light-emitting layer 771 and the light-emitting layer 772. A display apparatus with such a structure can be regarded as employing light-emitting devices with a tandem structure and having an SBS structure. Thus, the display apparatus can have advantages of both of a tandem structure and an SBS structure. Accordingly, a highly reliable light-emitting device capable of high-luminance light emission can be provided.

In FIG. 18E and FIG. 18F, light-emitting substances of different emission colors may be used for the light-emitting layer 771 and the light-emitting layer 772. White light emission can be obtained when the light-emitting layer 771 and the light-emitting layer 772 emit light of complementary colors. A color filter may be provided as the layer 764 illustrated in FIG. 18F. When white light passes through the color filter, light of a desired color can be obtained.

Although FIG. 18E and FIG. 18F illustrate examples where the light-emitting unit 763a includes one light-emitting layer 771 and the light-emitting unit 763b includes one light-emitting layer 772, one embodiment of the present invention is not limited thereto. Each of the light-emitting unit 763a and the light-emitting unit 763b may include two or more light-emitting layers.

Although FIG. 18E and FIG. 18F each illustrate an example of the light-emitting device that includes two light-emitting units, one embodiment of the present invention is not limited thereto. The light-emitting device may include three or more light-emitting units. Note that a structure that includes two light-emitting units and a structure that includes three light-emitting units may be referred to as a two-unit tandem structure and a three-unit tandem structure, respectively.

In FIG. 18E and FIG. 18F, the light-emitting unit 763a includes a layer 780a, the light-emitting layer 771, and a layer 790a, and the light-emitting unit 763b includes a layer 780b, the light-emitting layer 772, and a layer 790b.

In the case where the lower electrode 761 is an anode and the upper electrode 762 is a cathode, the layer 780a and the layer 780b each include one or more of a hole-injection layer, a hole-transport layer, and an electron-blocking layer. The layer 790a and the layer 790b each include one or more of an electron-injection layer, an electron-transport layer, and a hole-blocking layer. In the case where the lower electrode 761 is a cathode and the upper electrode 762 is an anode, the above structures of the layer 780a and the layer 790a are replaced with each other, and the above structures of the layer 780b and the layer 790b are also replaced with each other.

In the case where the lower electrode 761 is an anode and the upper electrode 762 is a cathode, for example, the layer 780a includes a hole-injection layer and a hole-transport layer over the hole-injection layer, and may further include an electron-blocking layer over the hole-transport layer. The layer 790a includes an electron-transport layer, and may further include a hole-blocking layer between the light-emitting layer 771 and the electron-transport layer. The layer 780b includes a hole-transport layer, and may further include an electron-blocking layer over the hole-transport layer. The layer 790b includes an electron-transport layer and an electron-injection layer over the electron-transport layer, and may further include a hole-blocking layer between the light-emitting layer 772 and the electron-transport layer. In the case where the lower electrode 761 is a cathode and the upper electrode 762 is an anode, for example, the layer 780a includes an electron-injection layer and an electron-transport layer over the electron-injection layer, and may further include a hole-blocking layer over the electron-transport layer. The layer 790a includes a hole-transport layer, and may further include an electron-blocking layer between the light-emitting layer 771 and the hole-transport layer. The layer 780b includes an electron-transport layer, and may further include a hole-blocking layer over the electron-transport layer. The layer 790b includes a hole-transport layer and a hole-injection layer over the hole-transport layer, and may further include an electron-blocking layer between the light-emitting layer 772 and the hole-transport layer.

In the case of manufacturing a light-emitting device with a tandem structure, two light-emitting units are stacked with the charge-generation layer 785 therebetween. The charge-generation layer 785 includes at least a charge-generation region. The charge-generation layer 785 has a function of injecting electrons into one of the two light-emitting units and injecting holes into the other when voltage is applied between the pair of electrodes.

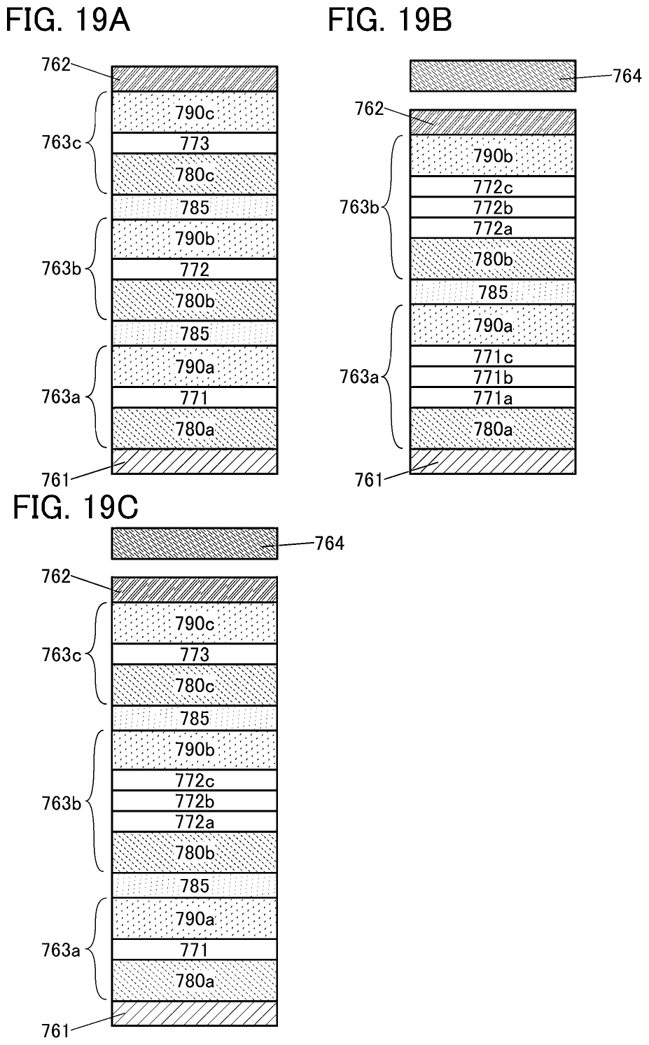

Structures illustrated in FIG. 19A to FIG. 19C can be given as examples of the light-emitting device with a tandem structure.

FIG. 19A illustrates a structure that includes three light-emitting units. In FIG. 19A, a plurality of light-emitting units (the light-emitting unit 763a, the light-emitting unit 763b, and a light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772, and the layer 790b. The light-emitting unit 763c includes a layer 780c, the light-emitting layer 773, and a layer 790c. Note that the layer 780c can have a structure applicable to the layer 780a and the layer 780b, and the layer 790c can have a structure applicable to the layer 790a and the layer 790b.

In FIG. 19A, the light-emitting layer 771, the light-emitting layer 772, and the light-emitting layer 773 preferably include light-emitting substances that emit light of the same color. Specifically, the light-emitting layer 771, the light-emitting layer 772, and the light-emitting layer 773 can each include a light-emitting substance that emits red (R) light (a so-called R\R\R three-unit tandem structure); the light-emitting layer 771, the light-emitting layer 772, and the light-emitting layer 773 can each include a light-emitting substance that emits green (G) light (a so-called a G\G\G three-unit tandem structure); or the light-emitting layer 771, the light-emitting layer 772, and the light-emitting layer 773 can each include a light-emitting substance that emits blue (B) light (a so-called B\B\B three-unit tandem structure). Note that “a\b” means that a light-emitting unit including a light-emitting substance that emits light of b is provided over a light-emitting unit including a light-emitting substance that emits light of a with a charge-generation layer therebetween, where a and b represent colors.

In FIG. 19A, light-emitting substances with different emission colors may be used for some or all of the light-emitting layer 771, the light-emitting layer 772, and the light-emitting layer 773. Examples of a combination of emission colors for the light-emitting layer 771, the light-emitting layer 772, and the light-emitting layer 773 include blue (B) for two of them and yellow (Y) for the other; and red (R) for one of them, green (G) for another, and blue (B) for the other.

Note that the structure including the light-emitting substances that emit light of the same color is not limited to the above structure. For example, a light-emitting device with a tandem structure may be employed in which light-emitting units each including a plurality of light-emitting layers are stacked as illustrated in FIG. 19B. FIG. 19B illustrates a structure in which two light-emitting units (the light-emitting unit 763a and the light-emitting unit 763b) are connected in series with the charge-generation layer 785 therebetween. The light-emitting unit 763a includes the layer 780a, a light-emitting layer 771a, a light-emitting layer 771b, a light-emitting layer 771c, and the layer 790a. The light-emitting unit 763b includes the layer 780b, a light-emitting layer 772a, a light-emitting layer 772b, a light-emitting layer 772c, and the layer 790b.

In FIG. 19B, the light-emitting unit 763a is configured to emit white light (W) by selecting light-emitting substances for the light-emitting layer 771a, the light-emitting layer 771b, and the light-emitting layer 771c so that their emission colors are complementary colors. Furthermore, the light-emitting unit 763b is configured to emit white light (W) by selecting light-emitting substances for the light-emitting layer 772a, the light-emitting layer 772b, and the light-emitting layer 772c so that their emission colors are complementary colors. That is, the structure illustrated in FIG. 19B is a two-unit tandem structure of WWW. Note that there is no particular limitation on the stacking order of the light-emitting substances having complementary emission colors. The practitioner can select the optimal stacking order as appropriate. Although not illustrated, a three-unit tandem structure of WWWWW or a tandem structure with four or more units may be employed.

In the case where a light-emitting device with a tandem structure is used, any of the following structures may be employed, for example: a BY or YB two-unit tandem structure that includes a light-emitting unit emitting yellow (Y) light and a light-emitting unit emitting blue (B) light; an R·G\B or B\R·G two-unit tandem structure that includes a light-emitting unit emitting red (R) light and green (G) light and a light-emitting unit emitting blue (B) light; a B\Y\B three-unit tandem structure that includes a light-emitting unit emitting blue (B) light, a light-emitting unit emitting yellow (Y) light, and a light-emitting unit emitting blue (B) light in this order; a BYG\B three-unit tandem structure that includes a light-emitting unit emitting blue (B) light, a light-emitting unit emitting yellow-green (YG) light, and a light-emitting unit emitting blue (B) light in this order; and a B\G\B three-unit tandem structure that includes a light-emitting unit emitting blue (B) light, a light-emitting unit emitting green (G) light, and a light-emitting unit emitting blue (B) light in this order. Note that “a\b” means that one light-emitting unit includes a light-emitting substance that emits light of a and a light-emitting substance that emits light of b.

As illustrated in FIG. 19C, a light-emitting unit that includes one light-emitting layer and a light-emitting unit that includes a plurality of light-emitting layers may be used in combination.

Specifically, in the structure illustrated in FIG. 19C, a plurality of light-emitting units (the light-emitting unit 763a, the light-emitting unit 763b, and the light-emitting unit 763c) are connected in series through the charge-generation layers 785. The light-emitting unit 763a includes the layer 780a, the light-emitting layer 771, and the layer 790a. The light-emitting unit 763b includes the layer 780b, the light-emitting layer 772a, the light-emitting layer 772b, the light-emitting layer 772c, and the layer 790b. The light-emitting unit 763c includes the layer 780c, the light-emitting layer 773, and the layer 790c.

As the structure illustrated in FIG. 19C, for example, a B\R·G·YG\B three-unit tandem structure in which the light-emitting unit 763a is a light-emitting unit that emits blue (B) light, the light-emitting unit 763b is a light-emitting unit that emits red (R), green (G), and yellow-green (YG) light, and the light-emitting unit 763c is a light-emitting unit that emits blue (B) light can be employed.

Examples of the number of stacked light-emitting units and the order of colors from the anode side include a two-unit structure of B and Y, a two-unit structure of B and a light-emitting unit X, a three-unit structure of B, Y, and B, and a three-unit structure of B, X, and B. Examples of the number of light-emitting layers stacked in the light-emitting unit X and the order of colors from an anode side include a two-layer structure of R and Y, a two-layer structure of R and G, a two-layer structure of G and R, a three-layer structure of G, R, and G, and a three-layer structure of R, G, and R. Another layer may be provided between two light-emitting layers.

Next, materials that can be used for the light-emitting device will be described.

A conductive film transmitting visible light is used for the electrode through which light is extracted, which is either the lower electrode 761 or the upper electrode 762. A conductive film reflecting visible light is preferably used for the electrode through which light is not extracted. In the case where the display apparatus includes a light-emitting device emitting infrared light, it is preferable that a conductive film transmitting visible light and infrared light be used for the electrode through which light is extracted, and a conductive film reflecting visible light and infrared light be used for the electrode through which light is not extracted.

A conductive film transmitting visible light may be used also for the electrode through which light is not extracted. In this case, this electrode is preferably provided between a reflective layer and the EL layer 763. In other words, light emitted from the EL layer 763 may be reflected by the reflective layer to be extracted from the display apparatus.

As a material that forms the pair of electrodes of the light-emitting device, a metal, an alloy, an electrically conductive compound, a mixture thereof, or the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). Other examples of the material include an element belonging to Group 1 or Group 2 of the periodic table that is not given above as an example (e.g., lithium, cesium, calcium, or strontium), a rare earth metal such as europium or ytterbium, an alloy containing an appropriate combination of any of these elements, and graphene.

The light-emitting device preferably employs a micro optical resonator (microcavity) structure. Therefore, one of the pair of electrodes included in the light-emitting device preferably includes an electrode having properties of transmitting and reflecting visible light (a transflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified.

Note that the transflective electrode can have a stacked-layer structure of a conductive layer that can be used as a reflective electrode and a conductive layer that can be used as an electrode having a property of transmitting visible light (also referred to as a transparent electrode).

The transparent electrode has a light transmittance higher than or equal to 40%. For example, an electrode having a visible light (light with a wavelength longer than or equal to 400 nm and shorter than 750 nm) transmittance higher than or equal to 40% is preferably used as the transparent electrode of the light-emitting device. The visible light reflectance of the transflective electrode is higher than or equal to 10% and lower than or equal to 95%, preferably higher than or equal to 30% and lower than or equal to 80%. The visible light reflectance of the reflective electrode is higher than or equal to 40% and lower than or equal to 100%, preferably higher than or equal to 70% and lower than or equal to 100%. These electrodes preferably have a resistivity lower than or equal to 1×10⁻² Ωcm.

The light-emitting device includes at least the light-emitting layer. In addition, the light-emitting device may further include, as a layer other than the light-emitting layer, a layer including a substance with a high hole-injection property, a substance with a high hole-transport property, a hole-blocking material, a substance with a high electron-transport property, an electron-blocking material, a substance with a high electron-injection property, a substance with a bipolar property (a substance with a high electron-transport property and a high hole-transport property), or the like. For example, the light-emitting device can include one or more of a hole-injection layer, a hole-transport layer, a hole-blocking layer, a charge-generation layer, an electron-blocking layer, an electron-transport layer, and an electron-injection layer in addition to the light-emitting layer.

Either a low molecular compound or a high molecular compound can be used for the light-emitting device, and an inorganic compound may be included. Each layer included in the light-emitting device can be formed by an evaporation method (including a vacuum evaporation method), a transfer method, a printing method, an ink-jet method, a coating method, or the like.

The light-emitting layer includes one or more kinds of light-emitting substances. As the light-emitting substance, a substance whose emission color is blue, violet, bluish violet, green, yellow green, yellow, orange, red, or the like is appropriately used. Alternatively, a substance that emits near-infrared light can be used as the light-emitting substance.

Examples of the light-emitting substance include a fluorescent material, a phosphorescent material, a TADF material, and a quantum dot material.

Examples of a fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of a phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative having an electron-withdrawing group as a ligand; a platinum complex; and a rare earth metal complex.

The light-emitting layer may include one or more kinds of organic compounds (e.g., a host material or an assist material) in addition to the light-emitting substance (a guest material). As the one or more kinds of organic compounds, one or both of a substance with a high hole-transport property (a hole-transport material) and a substance with a high electron-transport property (an electron-transport material) can be used. As the hole-transport material, a later-described material with a high hole-transport property that can be used for the hole-transport layer can be used. As the electron-transport material, a later-described material with a high electron-transport property that can be used for the electron-transport layer can be used. Alternatively, as the one or more kinds of organic compounds, a bipolar material or a TADF material may be used.

The light-emitting layer preferably includes a phosphorescent material and a combination of a hole-transport material and an electron-transport material that easily forms an exciplex, for example. Such a structure makes it possible to efficiently obtain light emission using ExTET (Exciplex-Triplet Energy Transfer), which is energy transfer from an exciplex to a light-emitting substance (a phosphorescent material). When a combination of materials is selected to form an exciplex that exhibits light emission whose wavelength overlaps with the wavelength of the lowest-energy-side absorption band of the light-emitting substance, energy can be transferred smoothly and light emission can be obtained efficiently. With the above structure, high efficiency, low-voltage driving, and a long lifetime of the light-emitting device can be achieved at the same time.

The hole-injection layer is a layer injecting holes from the anode to the hole-transport layer and including a material with a high hole-injection property. Examples of the material with a high hole-injection property include an aromatic amine compound and a composite material containing a hole-transport material and an acceptor material (electron-accepting material).

As the hole-transport material, a later-described material with a high hole-transport property that can be used for the hole-transport layer can be used.

As the acceptor material, an oxide of a metal belonging to any of Group 4 to Group 8 of the periodic table can be used, for example. Specific examples include molybdenum oxide, vanadium oxide, niobium oxide, tantalum oxide, chromium oxide, tungsten oxide, manganese oxide, and rhenium oxide. Among these, molybdenum oxide is particularly preferable since it is stable in the air, has a low hygroscopic property, and is easy to handle. Alternatively, an organic acceptor material containing fluorine can be used. Alternatively, an organic acceptor material such as a quinodimethane derivative, a chloranil derivative, or a hexaazatriphenylene derivative can be used.

As the material with a high hole-injection property, a material that contains a hole-transport material and the above-described oxide of a metal belonging to any of Group 4 to Group 8 of the periodic table (typically, molybdenum oxide) may be used, for example.

The hole-transport layer is a layer transporting holes, which are injected from the anode by the hole-injection layer, to the light-emitting layer. The hole-transport layer is a layer that includes a hole-transport material. As the hole-transport material, a substance having a hole mobility greater than or equal to 1×10⁻⁶ cm²/Vs is preferable. Note that other substances can also be used as long as the substances have a hole-transport property higher than an electron-transport property. As the hole-transport material, a material with a high hole-transport property such as a T-electron rich heteroaromatic compound (e.g., a carbazole derivative, a thiophene derivative, or a furan derivative) or an aromatic amine (a compound having an aromatic amine skeleton) is preferable.

The electron-blocking layer is provided in contact with the light-emitting layer. The electron-blocking layer includes a material having a hole-transport property and being capable of blocking electrons. Any of the materials having an electron-blocking property among the above hole-transport materials can be used for the electron-blocking layer.

The electron-blocking layer has a hole-transport property, and thus can also be referred to as a hole-transport layer. Among hole-transport layers, a layer having an electron-blocking property can also be referred to as an electron-blocking layer.

The electron-transport layer is a layer transporting electrons, which are injected from the cathode by the electron-injection layer, to the light-emitting layer. The electron-transport layer is a layer that includes an electron-transport material. As the electron-transport material, a substance having an electron mobility greater than or equal to 1×10⁻⁶ cm²/Vs is preferable. Note that other substances can also be used as long as the substances have an electron-transport property higher than a hole-transport property. As the electron-transport material, it is possible to use a material with a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a π-electron deficient heteroaromatic compound including a nitrogen-containing heteroaromatic compound.

The hole-blocking layer is provided in contact with the light-emitting layer. The hole-blocking layer includes a material having an electron-transport property and being capable of blocking holes. Any of the materials having a hole-blocking property among the above electron-transport materials can be used for the hole-blocking layer.

The hole-blocking layer has an electron-transport property, and thus can also be referred to as an electron-transport layer. Among electron-transport layers, a layer having a hole-blocking property can also be referred to as a hole-blocking layer.

The electron-injection layer is a layer injecting electrons from the cathode to the electron-transport layer and including a material with a high electron-injection property. As the material with a high electron-injection property, an alkali metal, an alkaline earth metal, or a compound thereof can be used. As the material with a high electron-injection property, a composite material containing an electron-transport material and a donor material (an electron-donating material) can also be used.

The difference between the LUMO level of the material with a high electron-injection property and the work function value of the material used for the cathode is preferably small (specifically, smaller than or equal to 0.5 eV).

The electron-injection layer can be formed using an alkali metal, an alkaline earth metal, or a compound thereof, such as lithium, cesium, ytterbium, lithium fluoride (LiF), cesium fluoride (CsF), calcium fluoride (CaFₓ, where X is a given number), 8-(quinolinolato) lithium (abbreviation: Liq), 2-(2-pyridyl) phenolatolithium (abbreviation: LiPP), 2-(2-pyridyl)-3-pyridinolato lithium (abbreviation: LiPPy), 4-phenyl-2-(2-pyridyl) phenolatolithium (abbreviation: LiPPP), lithium oxide (LiOₓ), or cesium carbonate, for example. The electron-injection layer may have a stacked-layer structure of two or more layers. In the stacked-layer structure, for example, lithium fluoride can be used for the first layer and ytterbium can be used for the second layer.

The electron-injection layer may include an electron-transport material. For example, a compound having an unshared electron pair and an electron deficient heteroaromatic ring can be used as the electron-transport material. Specifically, it is possible to use a compound having at least one of a pyridine ring, a diazine ring (a pyrimidine ring, a pyrazine ring, or a pyridazine ring), and a triazine ring.

Note that the lowest unoccupied molecular orbital (LUMO) level of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-di(naphthalen-2-yl)-4,7-diphenyl-1,10-phenanthroline (abbreviation: NBPhen), diquinoxalino[2,3-a: 2′,3′-c] phenazine (abbreviation: HATNA), 2,4,6-tris[3′-(pyridin-3-yl) biphenyl-3-yl]-1,3,5-triazine (abbreviation: TmPPPyTz), or the like can be used as the organic compound having an unshared electron pair. Note that NBPhen has a higher glass transition point (Tg) than BPhen and thus has high heat resistance.

As described above, the charge-generation layer includes at least a charge-generation region. The charge-generation region preferably includes an acceptor material, and for example, preferably includes a hole-transport material and an acceptor material that can be used for the above-described hole-injection layer.

The charge-generation layer preferably includes a layer including a material with a high electron-injection property. The layer can also be referred to as an electron-injection buffer layer. The electron-injection buffer layer is preferably provided between the charge-generation region and the electron-transport layer. By providing the electron-injection buffer layer, an injection barrier between the charge-generation region and the electron-transport layer can be lowered; thus, electrons generated in the charge-generation region can be easily injected into the electron-transport layer.

The electron-injection buffer layer preferably includes an alkali metal or an alkaline earth metal and can include an alkali metal compound or an alkaline earth metal compound, for example. Specifically, the electron-injection buffer layer preferably includes an inorganic compound containing an alkali metal and oxygen or an inorganic compound containing an alkaline earth metal and oxygen, further preferably contains an inorganic compound containing lithium and oxygen (e.g., lithium oxide (Li₂O)). Alternatively, a material that can be used for the above-described electron-injection layer can be favorably used for the electron-injection buffer layer.

The charge-generation layer preferably includes a layer including a material with a high electron-transport property. The layer can also be referred to as an electron-relay layer. The electron-relay layer is preferably provided between the charge-generation region and the electron-injection buffer layer. In the case where the charge-generation layer does not include an electron-injection buffer layer, the electron-relay layer is preferably provided between the charge-generation region and the electron-transport layer. The electron-relay layer has a function of preventing interaction between the charge-generation region and the electron-injection buffer layer (or the electron-transport layer) and smoothly transferring electrons.

A phthalocyanine-based material such as copper (II) phthalocyanine (abbreviation: CuPc) or a metal complex having a metal-oxygen bond and an aromatic ligand is preferably used for the electron-relay layer.

Note that the charge-generation region, the electron-injection buffer layer, and the electron-relay layer cannot be clearly distinguished from one another in some cases on the basis of the cross-sectional shapes, properties, or the like.

Note that the charge-generation layer may include a donor material instead of an acceptor material. For example, the charge-generation layer may include a layer including an electron-transport material and a donor material that can be used for the above-described electron-injection layer.

When the light-emitting units are stacked, providing a charge-generation layer between two light-emitting units can suppress an increase in driving voltage.

This embodiment can be combined with the other embodiments as appropriate.

At least part of the structure examples described in this embodiment, the drawings corresponding thereto, and the like can be combined with the other structure examples, the other drawings, and the like as appropriate.

At least part of this embodiment can be implemented in appropriate combination with the other embodiments described in this specification.

### Embodiment 6

In this embodiment, a light-receiving device that can be used for the display apparatus of one embodiment of the present invention and a display apparatus having a light-emitting and light-receiving function will be described.

For example, a pn or pin photodiode can be used as the light-receiving device. The light-receiving device functions as a photoelectric conversion device (also referred to as a photoelectric conversion element) that detects light entering the light-receiving device and generates electric charge. The amount of electric charge generated from the light-receiving device depends on the amount of light entering the light-receiving device.

It is particularly preferable to use an organic photodiode that includes a layer including an organic compound, as the light-receiving device. An organic photodiode, which is easily made thin, lightweight, and large in area and has a high degree of freedom for shape and design, can be used in a variety of display apparatuses.

[Light-receiving device]

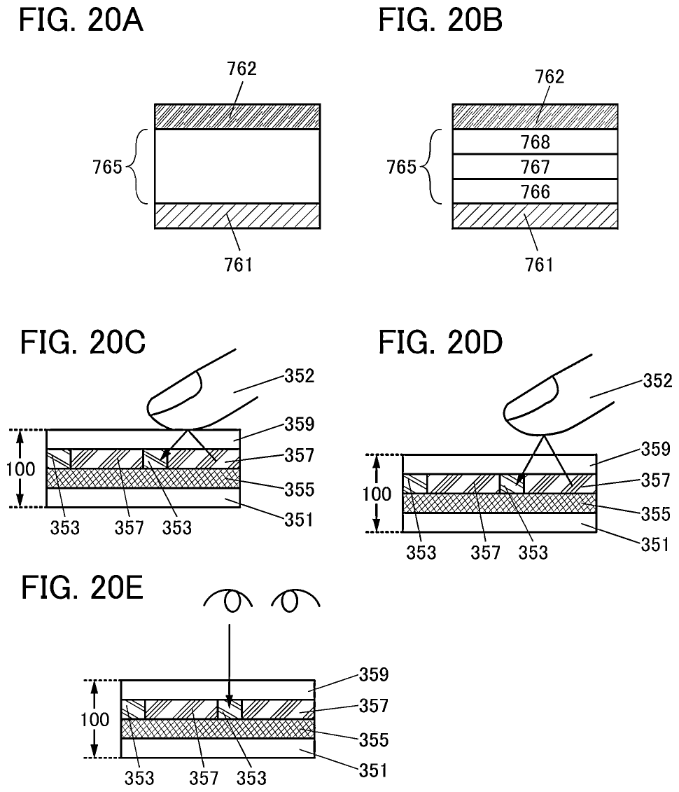

As illustrated in FIG. 20A, the light-receiving device includes a layer 765 between a pair of electrodes (the lower electrode 761 and the upper electrode 762). The layer 765 includes at least one active layer, and may further include another layer.

FIG. 20B illustrates a variation example of the EL layer 765 included in the light-receiving device illustrated in FIG. 20A. Specifically, the light-receiving device illustrated in FIG. 20B includes a layer 766 over the lower electrode 761, an active layer 767 over the layer 766, a layer 768 over the active layer 767, and the upper electrode 762 over the layer 768.

The active layer 767 functions as a photoelectric conversion layer.

In the case where the lower electrode 761 is an anode and the upper electrode 762 is a cathode, the layer 766 includes one or both of a hole-transport layer and an electron-blocking layer. The layer 768 includes one or both of an electron-transport layer and a hole-blocking layer. In the case where the lower electrode 761 is a cathode and the upper electrode 762 is an anode, the above structures of the layer 766 and the layer 768 are replaced with each other.

Here, the display apparatus of one embodiment of the present invention may include a layer common to the light-receiving device and the light-emitting device (also referred to as a continuous layer shared by the light-receiving device and the light-emitting device). Such a layer may have different functions in the light-emitting device and the light-receiving device in some cases. In this specification, the name of a component is based on its function in the light-emitting device in some cases. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer common to the light-receiving device and the light-emitting device may have the same function in both the light-emitting device and the light-receiving device. For example, a hole-transport layer functions as a hole-transport layer in both the light-emitting device and the light-receiving device, and an electron-transport layer functions as an electron-transport layer in both the light-emitting device and the light-receiving device.

Next, materials that can be used for the light-receiving device will be described.

Either a low molecular compound or a high molecular compound can be used for the light-receiving device, and an inorganic compound may be included. Each layer included in the light-receiving device can be formed by an evaporation method (including a vacuum evaporation method), a transfer method, a printing method, an ink-jet method, a coating method, or the like.

The active layer included in the light-receiving device includes a semiconductor. Examples of the semiconductor include an inorganic semiconductor such as silicon and an organic semiconductor containing an organic compound. This embodiment describes an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

Examples of an n-type semiconductor material included in the active layer include electron-accepting organic semiconductor materials such as fullerene (e.g., C₆₀ fullerene and C₇₀ fullerene) and fullerene derivatives. Examples of the fullerene derivative include[6,6]-phenyl-C₇₁-butyric acid methyl ester (abbreviation: PC71BM), [6,6]-phenyl-C₆₁-butyric acid methyl ester (abbreviation: PC61BM), and 1′,1″,4′,4″-tetrahydro-di[1,4] methanonaphthaleno[1,2:2′,3′,56,60:2″,3″] [5,6] fullerene-C₆₀ (abbreviation: ICBA).

Other examples of an n-type semiconductor material include perylenetetracarboxylic acid derivatives such as N,N′-dimethyl-3,4,9,10-perylenetetracarboxylic diimide (abbreviation: Me-PTCDI) and 2,2′-(5,5′-(thieno[3,2-b] thiophene-2,5-diyl)bis(thiophene-5,2-diyl))bis(methan-1-yl-1-ylidene)dimalononitrile (abbreviation: FT2TDMN).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper (II) phthalocyanine (abbreviation: CuPc), tetraphenyldibenzoperiflanthene (abbreviation: DBP), zinc phthalocyanine (abbreviation: ZnPc), tin (II) phthalocyanine (abbreviation: SnPc), quinacridone, and rubrene.

Other examples of a p-type semiconductor material include a carbazole derivative, a thiophene derivative, a furan derivative, and a compound having an aromatic amine skeleton. Other examples of a p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a rubrene derivative, a tetracene derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can increase the carrier-transport property.

For the active layer, a high molecular compound such as poly[4,8-bis[5-(2-ethylhexyl)-2-thienyl] benzo[1,2-b: 4,5-b′]dithiophene-2,6-diyl]-2,5-thiophenediyl[5,7-bis(2-ethylhexyl)-4,8-dioxo-4H,8H-benzo[1,2-c: 4,5-c′] dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

For example, the active layer is preferably formed by co-evaporation of an n-type semiconductor and a p-type semiconductor. Alternatively, the active layer may be formed by stacking an n-type semiconductor and a p-type semiconductor.

The active layer may include a mixture of three or more kinds of materials. For example, a third material may be mixed with an n-type semiconductor material and a p-type semiconductor material in order to extend the wavelength range. The third material may be a low molecular compound or a high molecular compound.

In addition to the active layer, the light-receiving device may further include a layer including a substance with a high hole-transport property, a substance with a high electron-transport property, a substance with a bipolar property (a substance with a high electron-transport property and a high hole-transport property), or the like. Without limitation to the above, the light-receiving device may further include a layer including a substance with a high hole-injection property, a hole-blocking material, a material with a high electron-injection property, an electron-blocking material, or the like. Layers other than the active layer included in the light-receiving device can be formed using a material that can be used for the light-emitting device.

As the hole-transport material or the electron-blocking material, a high molecular compound such as poly(3,4-ethylenedioxythiophene)/poly(styrenesulfonic acid) (PEDOT/PSS), or an inorganic compound such as molybdenum oxide or copper iodide (Cul) can be used, for example. As the electron-transport material or the hole-blocking material, an inorganic compound such as zinc oxide (ZnO), or an organic compound such as polyethylenimine ethoxylate (PEIE) can be used. The light-receiving device may include a mixed film of PEIE and ZnO, for example.

### [Display Apparatus Having Light Detection Function]

In the display apparatus of one embodiment of the present invention, the light-emitting devices are arranged in a matrix in a display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the proximity or contact of a target (e.g., a finger, a hand, or a pen) can be detected.

Furthermore, in the display apparatus of one embodiment of the present invention, the light-emitting devices can be used as a light source of the sensor. In the display apparatus of one embodiment of the present invention, when an object reflects (or scatters) light emitted by the light-emitting device included in the display portion, the light-receiving device can detect reflected light (or scattered light); thus, image capturing or touch detection is possible even in a dark place.

Accordingly, a light-receiving portion and a light source do not need to be provided separately from the display apparatus; hence, the number of components of an electronic device can be reduced. For example, it is not necessary to separately provide a biometric authentication device provided in the electronic device or a capacitive touch panel for scrolling or the like. Thus, with the use of the display apparatus of one embodiment of the present invention, the electronic device can be provided with reduced manufacturing cost.

Specifically, the display apparatus of one embodiment of the present invention includes a light-emitting device and a light-receiving device in a pixel. In the display apparatus of one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus that includes the organic EL device.

In the display apparatus that includes the light-emitting device and the light-receiving device in the pixel, the pixel has a light-receiving function; thus, the display apparatus can detect the contact or proximity of an object while displaying an image. For example, all the subpixels included in the display apparatus can display an image; alternatively, some of the subpixels can emit light as a light source, and the other subpixels can display an image.

In the case where the light-receiving device is used as an image sensor, the display apparatus can capture an image with the use of the light-receiving device. For example, the display apparatus of this embodiment can be used as a scanner.

For example, image capturing for personal authentication with the use of a fingerprint, a palm print, the iris, the shape of a blood vessel (including the shape of a vein and the shape of an artery), a face, or the like can be performed using the image sensor.

For example, an image of the periphery, surface, or inside (e.g., fundus) of an eye of a user of a wearable device can be captured using the image sensor. Therefore, the wearable device can have a function of detecting one or more selected from blinking, movement of an iris, and movement of an eyelid of the user.

The light-receiving device can be used for a touch sensor (also referred to as a direct touch sensor), a near touch sensor (also referred to as a hover sensor, a hover touch sensor, a contactless sensor, or a touchless sensor), or the like.

Here, the touch sensor or the near touch sensor can detect the proximity or contact of an object (e.g., a finger, a hand, or a pen).

The touch sensor can detect an object when the display apparatus and the object come in direct contact with each other. The near touch sensor can detect an object even when the object is not in contact with the display apparatus. For example, the display apparatus is preferably capable of detecting an object when the distance between the display apparatus and the object is greater than or equal to 0.1 mm and less than or equal to 300 mm, preferably greater than or equal to 3 mm and less than or equal to 50 mm. With this structure, the display apparatus can be operated without an object directly contacting with the display apparatus. In other words, the display apparatus can be operated in a contactless (touchless) manner. With the above structure, the display apparatus can have a reduced risk of being dirty or damaged, or can be operated without the object directly contacting with a dirt (e.g., dust or a virus) attached to the display apparatus.

The refresh rate can be variable in the display apparatus of one embodiment of the present invention. For example, the refresh rate is adjusted (adjusted within the range of 1 Hz to 240 Hz, for example) in accordance with contents displayed on the display apparatus, whereby power consumption can be reduced. The driving frequency of the touch sensor or the near touch sensor may be changed in accordance with the refresh rate. For example, when the refresh rate of the display apparatus is 120 Hz, the driving frequency of the touch sensor or the near touch sensor can be higher than 120 Hz (can typically be 240 Hz). With this structure, low power consumption can be achieved, and the response speed of the touch sensor or the near touch sensor can be increased.

The display apparatus 100 illustrated in FIG. 20C to FIG. 20E includes a layer 353 that includes the light-receiving device, a functional layer 355, and a layer 357 that includes the light-emitting device, between a substrate 351 and a substrate 359.

The functional layer 355 includes a circuit for driving the light-receiving device and a circuit for driving the light-emitting device. One or more of a switch, a transistor, a capacitor, a resistor, a wiring, a terminal, and the like can be provided in the functional layer 355. Note that in the case where the light-emitting device and the light-receiving device are driven by a passive-matrix method, a structure provided with neither a switch nor a transistor may be employed. For example, after light emitted by the light-emitting device in the layer 357 that includes the light-emitting device is reflected by a finger 352 in contact with the display apparatus 100 as illustrated in FIG. 20C, the light-receiving device in the layer 353 that includes the light-receiving device detects the reflected light. Thus, the contact of the finger 352 with the display apparatus 100 can be detected.

The display apparatus may have a function of detecting an object that is close to (i.e., not touching) the display apparatus as illustrated in FIG. 20D and FIG. 20E or capturing an image of such an object. FIG. 20D illustrates an example where a human finger is detected, and FIG. 20E illustrates an example where information on the periphery, surface, or inside of the human eye (e.g., the number of blinks, movement of an eyeball, and movement of an eyelid) is detected.

At least part of this embodiment can be implemented in combination with the other embodiments described in this specification as appropriate.

### Embodiment 7

In this embodiment, a structure example of a transistor that can be used in the display apparatus (display panel) of one embodiment of the present invention will be described. Specifically, the case of using a transistor containing silicon in a semiconductor where a channel is formed will be described.

One embodiment of the present invention is a display panel that includes a light-emitting device and a pixel circuit. The display panel can perform full-color display by including three types of light-emitting devices (also referred to as light-emitting elements) that emit red (R) light, green (G) light, and blue (B) light, for example.

Transistors containing silicon in their semiconductor layers where channels are formed are preferably used as all transistors included in the pixel circuit for driving the light-emitting device. As examples of silicon, single crystal silicon, polycrystalline silicon, amorphous silicon, and the like can be given. In particular, a transistor containing low-temperature polysilicon (LTPS) in its semiconductor layer (hereinafter also referred to as an LTPS transistor) is preferably used. The LTPS transistor has high field-effect mobility and favorable frequency characteristics.

With the use of transistors containing silicon, such as LTPS transistors, a circuit required to be driven at a high frequency (e.g., a source driver circuit) can be formed on the same substrate as the display portion. Thus, external circuits mounted on the display panel can be simplified, and parts costs and mounting costs can be reduced.

It is preferable to use transistors containing a metal oxide (hereinafter also referred to as an oxide semiconductor) in their semiconductors where channels are formed (such transistors are hereinafter also referred to as OS transistors) as at least one of the transistors included in the pixel circuit. An OS transistor has much higher field-effect mobility than a transistor containing amorphous silicon. In addition, the OS transistor has an extremely low leakage current between a source and a drain in an off state (hereinafter, also referred to as off-state current), and electric charge accumulated in a capacitor that is connected in series to the transistor can be retained for a long period. Furthermore, power consumption of the display panel can be reduced with the use of an OS transistor.

When an LTPS transistor is used as one or more of the transistors included in the pixel circuit and an OS transistor is used as the rest, a display panel with low power consumption and high driving capability can be achieved. In a more favorable example, it is preferable that an OS transistor be used as a transistor functioning as a switch for controlling electrical continuity between wirings and an LTPS transistor be used as a transistor for controlling current.

For example, one of the transistors included in the pixel circuit functions as a transistor for controlling current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the pixel circuit functions as a switch for controlling selection and non-selection of the pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

More specific structure examples will be described below with reference to drawings.

### Structure Example of Display Panel

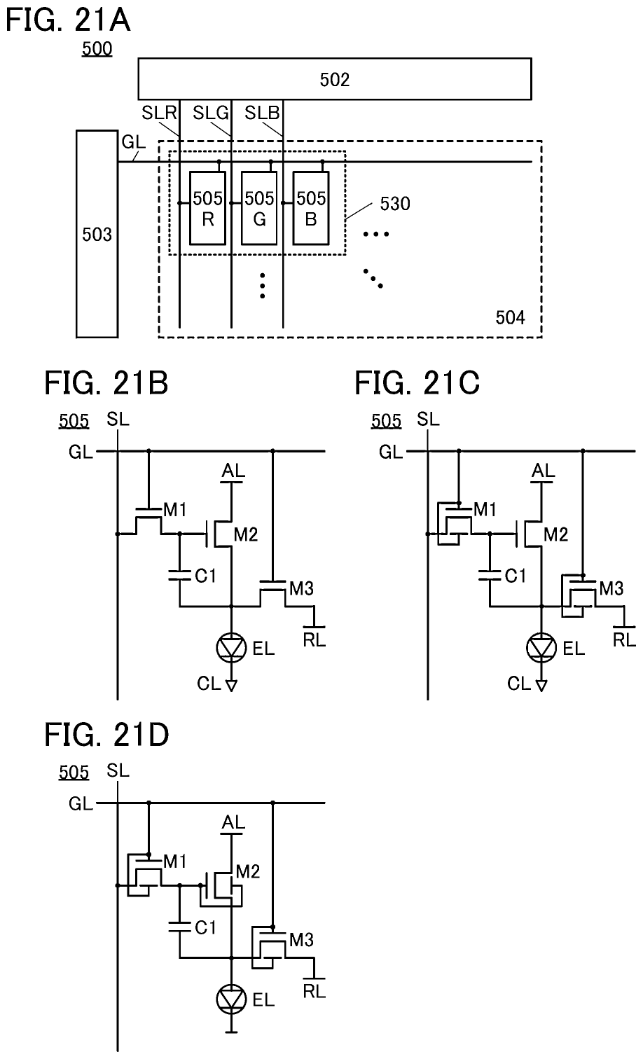

FIG. 21A is a block diagram of a display panel 500. The display panel 500 includes a display portion 504, a driver circuit portion 502, a driver circuit portion 503, and the like.

The display portion 504 includes a plurality of pixels 530 arranged in a matrix. The pixels 530 each include a subpixel 505R, a subpixel 505G, and a subpixel 505B. The subpixel 505R, the subpixel 505G, and the subpixel 505B each include a light-emitting device functioning as a display device.

The pixel 530 is electrically connected to a wiring GL, a wiring SLR, a wiring SLG, and a wiring SLB. The wiring SLR, the wiring SLG, and the wiring SLB are electrically connected to the driver circuit portion 502. The wiring GL is electrically connected to the driver circuit portion 503. The driver circuit portion 502 functions as a source line driver circuit (also referred to as a source driver), and the driver circuit portion 503 functions as a gate line driver circuit (also referred to as a gate driver). The wiring GL functions as a gate line, and the wiring SLR, the wiring SLG, and the wiring SLB each function as a source line.

The subpixel 505R includes a light-emitting device that emits red light. The subpixel 505G includes a light-emitting device that emits green light. The subpixel 505B includes a light-emitting device that emits blue light. Thus, the display panel 500 can perform full-color display. Note that the pixel 530 may include a subpixel that includes a light-emitting device emitting light of another color. For example, the pixel 530 may include, in addition to the three subpixels, a subpixel that includes a light-emitting device emitting white light, a subpixel that includes a light-emitting device emitting yellow light, or the like.

The wiring GL is electrically connected to the subpixel 505R, the subpixel 505G, and the subpixel 505B arranged in a row direction (the extending direction of the wiring GL). The wiring SLR, the wiring SLG, and the wiring SLB are electrically connected to the subpixels 505R, the subpixels 505G, and the subpixels 505B (not illustrated) arranged in a column direction (the extending direction of the wiring SLR and the like), respectively.

### Structure Example of Pixel Circuit

FIG. 21B is an example of a circuit diagram of a pixel 505 that can be used as the subpixel 505R, the subpixel 505G, and the subpixel 505B. The pixel 505 includes a transistor M1, a transistor M2, a transistor M3, a capacitor C1, and a light-emitting device EL. The wiring GL and a wiring SL are electrically connected to the pixel 505. The wiring SL corresponds to any of the wiring SLR, the wiring SLG, and the wiring SLB illustrated in FIG. 21A.

A gate of the transistor M1 is electrically connected to the wiring GL, one of a source and a drain of the transistor M1 is electrically connected to the wiring SL, and the other thereof is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting device EL, the other electrode of the capacitor C1, and one of a source and a drain of the transistor M3. A gate of the transistor M3 is electrically connected to the wiring GL, and the other of the source and the drain of the transistor M3 is electrically connected to a wiring RL. The other electrode of the light-emitting device EL is electrically connected to a wiring CL.

A data potential D is supplied to the wiring SL. A selection signal is supplied to the wiring GL. The selection signal includes a potential for bringing a transistor into a conducting state and a potential for bringing a transistor into a non-conducting state.

A reset potential is supplied to the wiring RL. An anode potential is supplied to the wiring AL. A cathode potential is supplied to the wiring CL. In the pixel 505, the anode potential is a potential higher than the cathode potential. The reset potential supplied to the wiring RL can be set such that the potential difference between the reset potential and the cathode potential is lower than the threshold voltage of the light-emitting device EL. The reset potential can be a potential higher than the cathode potential, a potential equal to the cathode potential, or a potential lower than the cathode potential.

The transistor M1 and the transistor M3 each function as a switch. The transistor M2 functions as a transistor for controlling current flowing through the light-emitting device EL. For example, it can be said that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all of the transistor M1 to the transistor M3. In this case, an LTPS transistor can be used as at least one of a plurality of transistors included in the driver circuit portion 502 and a plurality of transistors included in the driver circuit portion 503, and OS transistors can be used as the other transistors. For example, OS transistors can be used as the transistors provided in the display portion 504, and LTPS transistors can be used as the transistors provided in the driver circuit portion 502 and the driver circuit portion 503.

As the OS transistor, a transistor that includes an oxide semiconductor in its semiconductor layer where a channel is formed can be used. The semiconductor layer preferably includes indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more selected from aluminum, gallium, yttrium, and tin. It is particularly preferable to use an oxide containing indium, gallium, and zinc (also referred to as IGZO) for the semiconductor layer of the OS transistor. Alternatively, it is preferable to use an oxide containing indium, tin, and zinc. Further alternatively, it is preferable to use an oxide containing indium, gallium, tin, and zinc.

A transistor that includes an oxide semiconductor having a wider band gap and lower carrier density than silicon can achieve an extremely low off-state current. Thus, such a low off-state current enables long-term retention of electric charge accumulated in a capacitor that is connected to the transistor in series. Therefore, it is particularly preferable to use a transistor containing an oxide semiconductor as the transistor M1 and the transistor M3 each of which is connected to the capacitor C1 in series. The use of the transistor containing an oxide semiconductor as each of the transistor M1 and the transistor M3 can prevent leakage of electric charge retained in the capacitor C1 through the transistor M1 or the transistor M3. Furthermore, since electric charge retained in the capacitor C1 can be retained for a long time, a still image can be displayed for a long time without rewriting data in the pixel 505.

Note that although the transistor is illustrated as an n-channel transistor in FIG. 21B, a p-channel transistor can also be used.

The transistors included in the pixel 505 are preferably formed to be arranged over the same substrate.

Transistors each of which includes a pair of gates overlapping with each other with a semiconductor layer therebetween can be used as the transistors included in the pixel 505.

In the transistor that includes a pair of gates, the same potential is supplied to the pair of gates electrically connected to each other, which brings advantage that the transistor can have a higher on-state current and improved saturation characteristics. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel 505 illustrated in FIG. 21C is an example where a transistor that includes a pair of gates is used as each of the transistor M1 and the transistor M3. In each of the transistor M1 and the transistor M3, the pair of gates are electrically connected to each other. Such a structure can shorten the period in which data is written to the pixel 505.

The pixel 505 illustrated in FIG. 21D is an example where a transistor that includes a pair of gates is used as the transistor M2 in addition to the transistor M1 and the transistor M3. A pair of gates of the transistor M2 are electrically connected to each other. When such a transistor is used as the transistor M2, the saturation characteristics are improved, whereby emission luminance of the light-emitting device EL can be controlled easily and the display quality can be increased.

### Structure Example of Transistor

Cross-sectional structure examples of a transistor that can be used in the display panel described above are described below.

### Structure Example 1

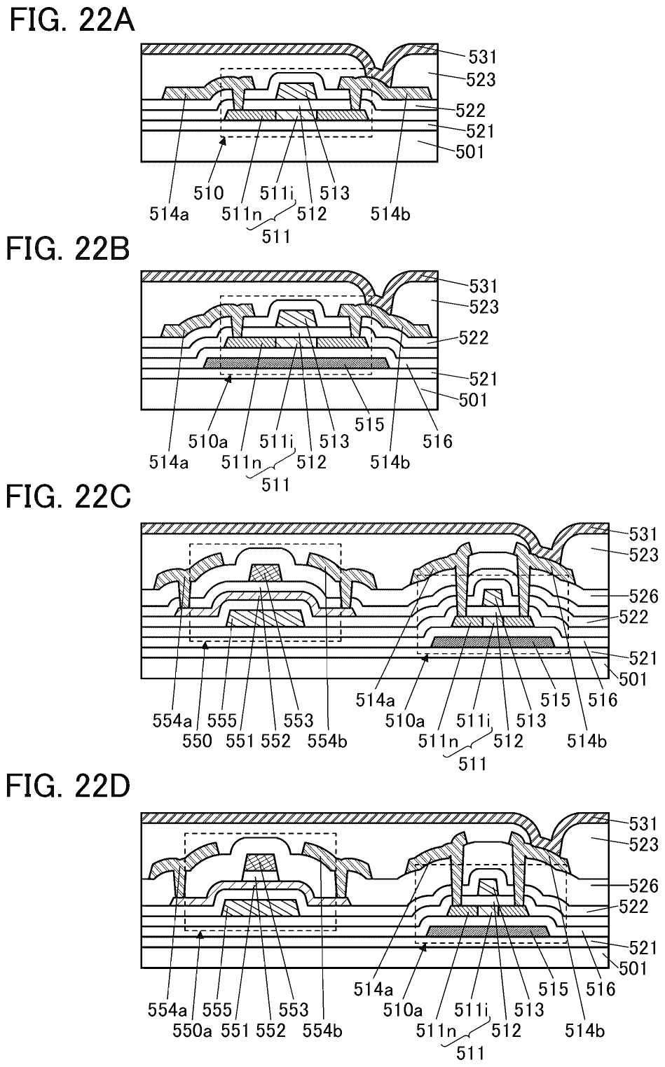

FIG. 22A is a cross-sectional view that includes a transistor 510.

The transistor 510 is provided over a substrate 501 and contains polycrystalline silicon in its semiconductor layer. For example, the transistor 510 corresponds to the transistor M2 in the pixel 505. In other words, FIG. 22A illustrates an example in which one of a source and a drain of the transistor 510 is electrically connected to a conductive layer 531 of the light-emitting device.

The transistor 510 includes a semiconductor layer 511, an insulating layer 512, a conductive layer 513, and the like. The semiconductor layer 511 includes a channel formation region 511i and low-resistance regions 511n. The semiconductor layer 511 includes silicon. The semiconductor layer 511 preferably includes polycrystalline silicon. Part of the insulating layer 512 functions as a gate insulating layer. Part of the conductive layer 513 functions as a gate electrode.

Note that the semiconductor layer 511 can include a metal oxide exhibiting semiconductor characteristics (also referred to as an oxide semiconductor). In this case, the transistor 510 can be referred to as an OS transistor.

The low-resistance region 511n is a region including an impurity element. For example, in the case where the transistor 510 is an n-channel transistor, phosphorus, arsenic, or the like is added to the low-resistance region 511n. Meanwhile, in the case where the transistor 510 is a p-channel transistor, boron, aluminum, or the like is added to the low-resistance region 511n. In addition, in order to control the threshold voltage of the transistor 510, the above-described impurity may be added to the channel formation region 511i.

An insulating layer 521 is provided over the substrate 501. The semiconductor layer 511 is provided over the insulating layer 521. The insulating layer 512 is provided to cover the semiconductor layer 511 and the insulating layer 521. The conductive layer 513 is provided at a position that is over the insulating layer 512 and overlaps with the semiconductor layer 511.

An insulating layer 522 is provided to cover the conductive layer 513 and the insulating layer 512. A conductive layer 514a and a conductive layer 514b are provided over the insulating layer 522. The conductive layer 514a and the conductive layer 514b are each electrically connected to the low-resistance region 511n in the opening portion provided in the insulating layer 522 and the insulating layer 512. Part of the conductive layer 514a functions as one of a source electrode and a drain electrode, and part of the conductive layer 514b functions as the other of the source electrode and the drain electrode. An insulating layer 523 is provided to cover the conductive layer 514a, the conductive layer 514b, and the insulating layer 522.

The conductive layer 531 functioning as a pixel electrode is provided over the insulating layer 523. The conductive layer 531 is provided over the insulating layer 523 and is electrically connected to the conductive layer 514b through an opening provided in the insulating layer 523. Although not illustrated here, an EL layer and a common electrode can be stacked over the conductive layer 531.

### Structure Example 2

FIG. 22B illustrates a transistor 510a that includes a pair of gate electrodes. The transistor 510a illustrated in FIG. 22B is different from the transistor illustrated in FIG. 22A mainly in including a conductive layer 515 and an insulating layer 516.

The conductive layer 515 is provided over the insulating layer 521. The insulating layer 516 is provided to cover the conductive layer 515 and the insulating layer 521. The semiconductor layer 511 is provided such that at least the channel formation region 511i overlaps with the conductive layer 515 with the insulating layer 516 therebetween.

In the transistor 510a illustrated in FIG. 22B, part of the conductive layer 513 functions as a first gate electrode, and part of the conductive layer 515 functions as a second gate electrode. At this time, part of the insulating layer 512 functions as a first gate insulating layer, and part of the insulating layer 516 functions as a second gate insulating layer.

Here, to electrically connect the first gate electrode to the second gate electrode, the conductive layer 513 is electrically connected to the conductive layer 515 through an opening portion provided in the insulating layer 512 and the insulating layer 516 in a region not illustrated. To electrically connect the second gate electrode to a source or a drain, the conductive layer 515 is electrically connected to the conductive layer 514a or the conductive layer 514b through an opening portion provided in the insulating layer 522, the insulating layer 512, and the insulating layer 516 in a region not illustrated.

In the case where LTPS transistors are used as all of the transistors included in the pixel 505, the transistor 510 illustrated in FIG. 22A as an example or the transistor 510a illustrated in FIG. 22B as an example can be used. In this case, the transistors 510a may be used as all of the transistors included in the pixels 505, the transistors 510 may be used as all of the transistors, or the transistors 510a and the transistors 510 may be used in combination.

### Structure Example 3

Described below is an example of a structure that includes both a transistor containing silicon in its semiconductor layer and a transistor containing a metal oxide in its semiconductor layer.

FIG. 22C is a schematic cross-sectional view that includes the transistor 510a and a transistor 550.

Structure example 1 described above can be referred to for the transistor 510a. Although an example of using the transistor 510a is described here, a structure that includes the transistor 510 and the transistor 550 or a structure that includes all of the transistor 510, the transistor 510a, and the transistor 550 may alternatively be employed.

The transistor 550 is a transistor containing a metal oxide in its semiconductor layer. The structure illustrated in FIG. 22C is an example in which the transistor 550 and the transistor 510a respectively correspond to the transistor M1 and the transistor M2 in the pixel 505, for example. That is, FIG. 22C illustrates an example in which one of a source and a drain of the transistor 510a is electrically connected to the conductive layer 531.

Moreover, FIG. 22C illustrates an example in which the transistor 550 includes a pair of gates.

The transistor 550 includes a conductive layer 555, the insulating layer 522, a semiconductor layer 551, an insulating layer 552, a conductive layer 553, and the like. Part of the conductive layer 553 functions as a first gate of the transistor 550, and part of the conductive layer 555 functions as a second gate of the transistor 550. In this case, part of the insulating layer 552 functions as a first gate insulating layer of the transistor 550, and part of the insulating layer 522 functions as a second gate insulating layer of the transistor 550.

The conductive layer 555 is provided over the insulating layer 512. The insulating layer 522 is provided to cover the conductive layer 555. The semiconductor layer 551 is provided over the insulating layer 522. The insulating layer 552 is provided to cover the semiconductor layer 551 and the insulating layer 522. The conductive layer 553 is provided over the insulating layer 552 and includes a region overlapping with the semiconductor layer 551 and the conductive layer 555.

An insulating layer 526 is provided to cover the insulating layer 552 and the conductive layer 553. A conductive layer 554a and a conductive layer 554b are provided over the insulating layer 526. The conductive layer 554a and the conductive layer 554b are electrically connected to the semiconductor layer 551 in opening portions provided in the insulating layer 526 and the insulating layer 552. Part of the conductive layer 554a functions as one of a source electrode and a drain electrode and part of the conductive layer 554b functions as the other of the source electrode and the drain electrode. The insulating layer 523 is provided to cover the conductive layer 554a, the conductive layer 554b, and the insulating layer 526.

Here, the conductive layer 514a and the conductive layer 514b electrically connected to the transistor 510a are preferably formed by processing the same conductive film as the conductive layer 554a and the conductive layer 554b. In FIG. 22C, the conductive layer 514a, the conductive layer 514b, the conductive layer 554a, and the conductive layer 554b are formed on the same plane (i.e., in contact with the top surface of the insulating layer 526) and include the same metal element. In this case, the conductive layer 514a and the conductive layer 514b are electrically connected to the low-resistance regions 511n through openings provided in the insulating layer 526, the insulating layer 552, the insulating layer 522, and the insulating layer 512. This can simplify the fabricating process and is thus preferable.

Moreover, the conductive layer 513 functioning as the first gate electrode of the transistor 510a and the conductive layer 555 functioning as the second gate electrode of the transistor 550 are preferably formed by processing the same conductive film. FIG. 22C illustrates a structure where the conductive layer 513 and the conductive layer 555 are formed on the same plane (i.e., in contact with the top surface of the insulating layer 512) and include the same metal element. This can simplify the fabricating process and is thus preferable.

In the structure in FIG. 22C, the insulating layer 552 functioning as the first gate insulating layer of the transistor 550 covers an end portion of the semiconductor layer 551; however, the insulating layer 552 may be processed to have the same or substantially the same top surface shape as the conductive layer 553 as in the transistor 550a illustrated in FIG. 22D.

Note that in this specification and the like, the expression “top surface shapes are substantially the same” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is located inward from the lower layer or the upper layer is located outward from the lower layer; such cases are also represented by the expression “top surface shapes are substantially the same”.

Although the example in which the transistor 510a corresponds to the transistor M2 and is electrically connected to the pixel electrode is described here, one embodiment of the present invention is not limited thereto. For example, a structure in which the transistor 550 or the transistor 550a corresponds to the transistor M2 may be employed. In that case, the transistor 510a corresponds to the transistor M1, the transistor M3, or another transistor.

At least part of this embodiment can be implemented in appropriate combination with the other embodiments described in this specification.

### Embodiment 8

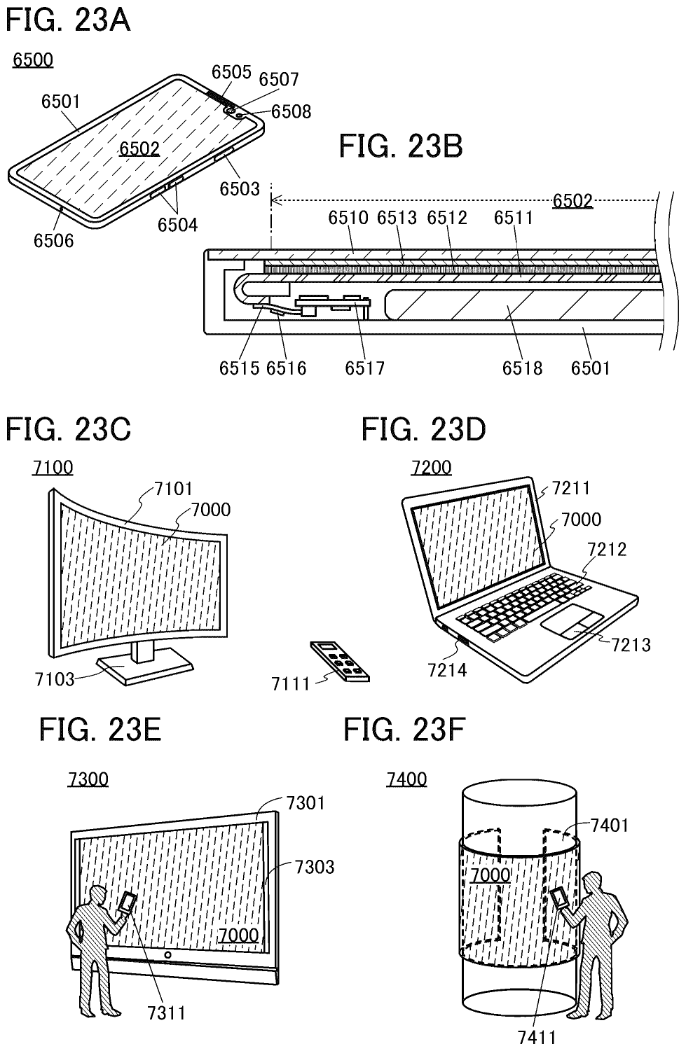

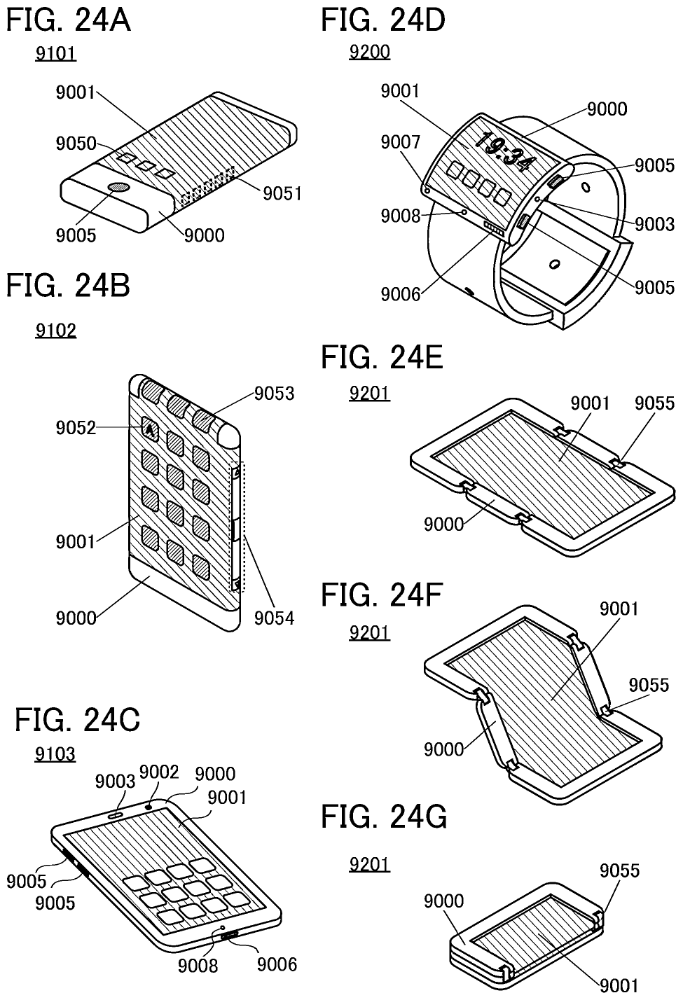

In this embodiment, electronic devices of embodiments of the present invention are described with reference to FIG. 23 and FIG. 24.

The image processing system in this embodiment can be used for a variety of electronic devices having a function of displaying images. Thus, the power consumption of the electronic devices provided with display portions can be significantly reduced.

Examples of the electronic devices include a digital camera, a digital video camera, a digital photo frame, a mobile phone, a portable game console, a portable information terminal, and an audio reproducing device, in addition to electronic devices with a relatively large screen, such as a television device, a desktop or notebook personal computer, a monitor of a computer or the like, digital signage, and a large game machine like a pachinko machine.

In particular, the display panel of one embodiment of the present invention can have high definition, and thus can be suitably used for an electronic device having a relatively small display portion. Examples of such an electronic device include watch-type and bracelet-type information terminal devices (wearable devices).

The resolution of the display panel of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a resolution of 4K, 8K, or higher is preferable. The pixel density (definition) of the display panel of one embodiment of the present invention is preferably higher than or equal to 50 ppi, further preferably higher than or equal to 100 ppi, still further preferably higher than or equal to 300 ppi, yet still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display panel having one or both of high resolution and high definition, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 23A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display panel of one embodiment of the present invention can be used for the display portion 6502.

FIG. 23B is a schematic cross-sectional view that includes an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 23C illustrates an example of a television device. In a television device 7100, a display portion 7000 is incorporated in a housing 7101. Here, the housing 7101 is supported by a stand 7103.

Operation of the television device 7100 illustrated in FIG. 23C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may be provided with a display portion for displaying information output from the remote control 7111. With operation keys or a touch panel provided in the remote control 7111, channels and volume can be controlled and videos displayed on the display portion 7000 can be operated.

Note that the television device 7100 has a structure in which a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 23D illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

FIG. 23E and FIG. 23F illustrate examples of digital signage.

Digital signage 7300 illustrated in FIG. 23E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 23F illustrates digital signage 7400 attached to a cylindrical pillar 7401. The digital signage 7400 includes the display portion 7000 provided along a curved surface of the pillar 7401. A larger area of the display portion 7000 allows a larger amount of information to be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 23E and FIG. 23F, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

The display panel of one embodiment of the present invention can be used for the display portion 7000 illustrated in each of FIG. 23C to FIG. 23F.

Electronic devices illustrated in FIG. 24A to FIG. 24G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The electronic devices illustrated in FIG. 24A to FIG. 24G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may include a plurality of display portions. In addition, the electronic devices may each include a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 24A to FIG. 24G are described below.

FIG. 24A is a perspective view illustrating a portable information terminal 9101. The portable information terminal 9101 can be used as a smartphone, for example. Note that the portable information terminal 9101 may include the speaker 9003, the connection terminal 9006, the sensor 9007, or the like. The portable information terminal 9101 can display characters and image information on its plurality of surfaces. FIG. 24A illustrates an example where three icons 9050 are displayed. Furthermore, information 9051 indicated by dashed rectangles can be displayed on another surface of the display portion 9001. Examples of the information 9051 include notification of reception of an e-mail, an SNS message, an incoming call, or the like, the title and sender of an e-mail, an SNS message, or the like, the date, the time, remaining battery, and the radio field intensity. Alternatively, the icon 9050 or the like may be displayed at the position where the information 9051 is displayed.

FIG. 24B is a perspective view illustrating a portable information terminal 9102. The portable information terminal 9102 has a function of displaying information on three or more surfaces of the display portion 9001. Here, an example is illustrated in which information 9052, information 9053, and information 9054 are displayed on different surfaces. For example, a user can check the information 9053 displayed in a position that can be observed from above the portable information terminal 9102, with the portable information terminal 9102 put in a breast pocket of his/her clothes. The user can see the display without taking out the portable information terminal 9102 from the pocket and decide whether to answer the call, for example.

FIG. 24C is a perspective view illustrating a tablet terminal 9103. The tablet terminal 9103 is capable of executing a variety of applications such as mobile phone calls, e-mailing, viewing and editing texts, music reproduction, Internet communication, and a computer game, for example. The tablet terminal 9103 includes the display portion 9001, the camera 9002, the microphone 9008, and the speaker 9003 on the front surface of the housing 9000; the operation keys 9005 as buttons for operation on the left side surface of the housing 9000; and the connection terminal 9006 on the bottom surface of the housing 9000.

FIG. 24D is a perspective view illustrating a watch-type portable information terminal 9200. For example, the portable information terminal 9200 can be used as a Smartwatch (registered trademark). The display surface of the display portion 9001 is curved, and display can be performed on the curved display surface. Furthermore, for example, mutual communication between the portable information terminal 9200 and a headset capable of performing wireless communication can be performed, and thus hands-free calling is possible. With the connection terminal 9006, the portable information terminal 9200 can perform mutual data transmission with another information terminal and charging. Note that the charging operation may be performed by wireless power feeding.

FIG. 24E to FIG. 24G are perspective views illustrating a foldable portable information terminal 9201. FIG. 24E is a perspective view of an opened state of the portable information terminal 9201, FIG. 24G is a perspective view of a folded state thereof, and FIG. 24F is a perspective view of a state in the middle of change from one of FIG. 24E and FIG. 24G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in appropriate combination with the other embodiments described in this specification.

### REFERENCE NUMERALS

10A: electronic device, 10: electronic device, 11: display portion, 12: arithmetic portion, 13: image processing portion, 14: communication portion, 15: sensor portion, 16: image capturing portion, 17: audio control portion, 20: housing, 21: display apparatus, 22: input device, 23: driver portion, 24: driver portion, 25: area, 31: illuminance sensor, 32: camera, 33: speaker, 34: microphone, 35: camera, 36: acceleration sensor, 40: user, 41: image, 42: image, 50: contact position, 51: region, 52: region, 53: region, 55: region, 61: main body, 62: keyboard, 63: mouse, 70: display portion, 71: cursor, 72: window, 73: window, 74: background, 80: server, 81: arithmetic portion, 82: image processing portion, 83: communication portion

1. An image processing system comprising a display portion, an input portion, an arithmetic portion, and an image processing portion,
wherein the input portion is configured to obtain positional information on pointing operation by a user,
wherein the arithmetic portion is configured to define a first region and a second region in accordance with the positional information,
wherein the image processing portion is configured to execute image processing on a portion of a first image to generate a second image, the portion corresponding to the first region, and
wherein the display portion is configured to display the second image.

2. The image processing system according to claim 1, further comprising a communication portion,
wherein the communication portion is configured to communicate with a server, and
wherein the image processing portion is provided in the server.

3. The image processing system according to claim 1, further comprising a communication portion,
wherein the communication portion is configured to communicate with a server, and
wherein the image processing portion and the arithmetic portion are provided in the server.

4. The image processing system according to claim 1,
wherein the image processing is configured to make resolution of the first region lower than resolution of the second region.

5. The image processing system according to claim 1,
wherein the image processing is configured to make a frequency in the first region lower than a frequency in the second region.

6. The image processing system according to claim 1,
wherein the image processing is configured to make a gray level in the first region lower than a gray level in the second region.

7. The image processing system according to claim 1,
wherein the input portion comprises a touch sensor, and
wherein the touch sensor comprises at least one of a capacitive sensor and an organic photodiode.

8. The image processing system according to claim 1,
wherein the first, region is configured to display a first moving image, and
wherein the second, region is configured to display at least one of a second moving image moving more slowly than the first moving image in the first region and a still image.

9. The image processing system according to claim 1,
wherein the second region includes coordinates pointed by the user, and
wherein the first region surrounds the second region.

10. The image processing system according to claim 1,
wherein pixel density of the display portion is higher than or equal to 50 ppi and lower than or equal to 1500 ppi.
